(19) United States
(12) Patent Application Publication
(10) Pub. No.: US 2014/0353705 A1
(43) Pub. Date: Dec. 4, 2014

(54) SEMICONDUCTOR LIGHT EMITTING ELEMENT, METHOD OF MANUFACTURING SEMICONDUCTOR LIGHT EMITTING ELEMENT, SEMICONDUCTOR LIGHT EMITTING DEVICE AND SUBSTRATE

(71) Applicant: Sharp Kabushiki Kaisha, Osaka-shi, Osaka (JP)

(72) Inventors: Takeshi Kamikawa, Osaka-Shi (JP); Masaaki Katoh, Osaka-shi (JP); Tetsuya Hanamoto, Osaka-shi (JP)

(73) Assignee: SHARP KABUSHIKI KAISHA, Osaka-shi, Osaka (JP)

(21) Appl. No.: 14/370,034

(22) PCT Filed: Mar. 7, 2013
(86) PCT No.: PCT/JP2013/056275

§ 371 Date: Jun. 30, 2014

(30) Foreign Application Priority Data
Mar. 23, 2012 (JP) 2012-067132
Jul. 17, 2012 (JP) 2012-158521

(51) Int. Cl. H01L 33/58; H01L 21/78; H01L 33/00; H01L 21/268; H01L 33/64; H01L 33/42

(52) U.S. Cl. CPC H01L 33/58; H01L 33/641; H01L 33/42; H01L 33/005; H01L 21/268; H01L 21/78; H01L 2933/0058
USPC 257/98; 438/29

(57) ABSTRACT

A semiconductor light emitting element includes a transparent substrate that transmits light emitted from said semiconductor light emitting element and a multi-layered structure formed on the transparent substrate. The multi-layered structure includes a semiconductor multi-layered film consisting of an n-type layer, an MQW light emitting layer and a p-type layer. The transparent substrate includes a light scattering structure formed in the transparent substrate for scattering the light that entered the substrate.

### CROSS-REFERENCE TO RELATED APPLICATIONS

This application is a national phase filing under 35 U.S.C. §371 of International Application No. PCT/JP2013/056275, filed on Mar. 7, 2013, and which claims priority to Japanese Patent Application Nos. 2012-067132, filed on Mar. 23, 2012, and 2012-158521, filed on Jul. 17, 2012, the contents of which prior applications are incorporated herein by reference.

### FIELD OF THE INVENTION

The present invention relates to a technique of improving efficiency of extracting light to the outside of a semiconductor light emitting element.

### BACKGROUND OF THE INVENTION

A semiconductor light emitting element using a transparent substrate of, for example, sapphire substrate, has been known as an example of the light emitting element using nitride-based semiconductor. In such a semiconductor light emitting element, a multi-layered film of nitride-based semiconductor including a light emitting layer is formed on the transparent substrate. On the multi-layered film, typically, an electrode layer including a transparent electrode and a pad electrode is formed.

In a semiconductor light emitting element, light emitted downward from the light emitting layer enters the transparent substrate and is reflected from the back surface of the substrate. The light reflected from the back surface of the substrate returns to the upper part of the semiconductor light emitting element, and part of the light enters the semiconductor multi-layered film. The light that has entered the multi-layered film passes through the multi-layered film and the like and is taken out to the outside of the light emitting element. Part of the light, however, is absorbed, for example, by the transparent electrode, the pad electrode and the light emitting layer. Therefore, light extracting efficiency is higher when the light reflected from the back surface of the substrate is taken out from a side surface of the transparent substrate than when the light is taken out from the upper surface side (on which the multi-layered film is formed) of the light emitting element.

By way of example, assume that a sapphire substrate is used as the transparent substrate and the light is directly extracted to the air from a side surface of the sapphire substrate. Here, the angle of total reflection (θ_{side}: if the light is incident on the side surface of substrate with this or larger angle with respect to the vertical direction, the light is totally reflected) at the interface between the sapphire substrate (refractive index=1.78) and the air (refractive index=1) is θ_{side}≧34.18°. Specifically, consider the light emitted downward from the light emitting layer and entered the sapphire substrate. Of the light beams directly proceeded to or reflected by the back surface of sapphire substrate and directed to the side surface of sapphire substrate, those incident on the side surface of sapphire substrate with the angle of 34.18°≦θ_{side}≦90° with respect to the vertical direction of the substrate side surface are not taken out from the side surface of sapphire substrate but returned toward the side of multi-layered film of nitride-based semiconductor including the light emitting layer formed on the sapphire substrate. On the other hand, light beams with the incident angle of θ_{side}<34.18° are emitted to the air from the side surface of sapphire substrate.

A semiconductor light emitting element is generally mounted on a stem or the like and sealed with transparent resin having the refractive index of about 1.4 to about 1.5. Here, the difference in refractive index between the transparent substrate and the transparent resin is smaller than the difference in refractive index between the transparent substrate and the air. Therefore, total reflection of light at the side surface of transparent substrate is less likely than when the side surface of transparent substrate is in contact with the air. As a result, it becomes easier to extract light with higher efficiency from the side surface of transparent substrate.

By way of example, assuming that the sealing resin has the refractive index of 1.5, the angle of total reflection at the interface with the side surface of sapphire substrate is θ_{side}≧57.43°. Specifically, consider the light emitted downward from the light emitting layer and entered the sapphire substrate. Of the light beams directly proceeded to or reflected by the back surface of sapphire substrate and directed to the side surface of sapphire substrate, those incident on the side surface of sapphire substrate with the angle of 57.43°≦θ_{side}≦90° with respect to the vertical direction of the substrate side surface are not taken out from the side surface of sapphire substrate but returned toward the side of multi-layered film of nitride-based semiconductor including the light emitting layer formed on the sapphire substrate. On the other hand, light beams with the incident angle of θ_{side}<57.43° are emitted to the transparent resin from the side surface of sapphire substrate. In this manner, by sealing the semiconductor light emitting element with the transparent resin, it becomes possible to extract larger amount of light from the side surface of sapphire substrate. It is noted, however, that still some amount of light is totally reflected at the side surface of sapphire substrate. Therefore, it is necessary to further improve the light extraction efficiency to minimize the totally reflected light.

Patent Literature 1 specified below proposes, as a solution to such a problem, to form irregularities on the back surface of transparent substrate. According to Patent Literature 1, light beams emitted downward from the light emitting layer, incident on the sapphire substrate, mirror-reflected by the back surface of sapphire substrate and again returned to the side of light emitting layer come to be reflected at angles different from those of the conventional examples because of the irregularities and, hence, it becomes easier to extract light from the side surface of substrate. According to Patent Literature 1, if the back surface of transparent substrate is in contact with air, there is a large difference in refractive index and, therefore, remarkable light scattering effect can be attained by the structure with irregularities. This enables improved efficiency of light extraction to the outside.

### PATENT LITERATURE

PTL 1: Japanese Patent Laying-Open No. 2002-368261

### SUMMARY OF THE INVENTION

When a light emitting element is mounted on a stem or the like, however, generally a transparent silicone resin or the like having refractive index of about 1.5 is used as a die bonding paste. In that case, the difference in refractive index becomes smaller and the light scattering effect attained by the structure with irregularities is reduced. Therefore, when packaging of a semiconductor light emitting element is considered, it is difficult to improve the efficiency of extracting light to the outside using the configuration of Patent Literature 1.

The present invention was made to solve such a problem, and an object of the present invention is to provide a semiconductor light emitting element enabling improvement of light extraction efficiency, a method of manufacturing such a semiconductor light emitting element, a semiconductor light emitting device and a substrate mounting such a semiconductor light emitting element.

In order to attain the above-described object, according to a first aspect, the present invention provides a semiconductor light emitting element, including: a transparent substrate having transmittance to light emitted from the semiconductor light emitting element; and a multi-layered structure including a semiconductor multi-layered film, formed on the transparent substrate. The transparent substrate includes light scattering means formed in the transparent substrate for scattering the light that has entered the substrate.

In the semiconductor light emitting element using a transparent substrate, light scattering means is formed inside the transparent substrate. On the transparent substrate, a multi-layered structure including a semiconductor multi-layered film is formed, and the light emitted by the multi-layered structure enters the transparent substrate. The light scattering means scatters the light from the multi-layered structure that has entered the transparent substrate, and thereby makes it easier to take out the light from the side surface of transparent substrate. Thus, the efficiency of extracting light to the outside can be improved.

Even when the semiconductor light emitting element is sealed by a transparent resin having the refractive index of about 1.4 to about 1.5, it is possible to take out the light that has entered the transparent substrate from the side surface of transparent substrate with high efficiency, because of the light scattering means. Further, since the light scattering means is formed within the transparent substrate, the effect of scattering light is not much degraded even when the light emitting element is mounted on a stem or the like using a die bonding paste of, for example, transparent silicone resin having refractive index of about 1.5. Therefore, by the configuration described above, it is possible to improve the efficiency of extracting light to the outside, even when the semiconductor light emitting element is in the mounted state.

Preferably, the light scattering means reflects light such that incident angle of the light to a side surface of the transparent substrate becomes smaller.

By the light scattering means configured in this manner, the efficiency of extracting light to the outside can further be improved.

More preferably, the light scattering means includes a plurality of light scattering portions formed in the transparent substrate.

Thus, efficiency of extracting light to the outside can easily be improved.

More preferably, the plurality of light scattering portions are dispersed in a plane in the transparent substrate, and the plurality of light scattering portions dispersed in a plane forms a scatterer layer. Since the scatterer layer realized by a plurality of light scattering portions is formed in the transparent substrate, it becomes possible to scatter the light that has entered from the multi-layered structure to the transparent substrate at the scatterer layer with high efficiency. As a result, very high light scattering effect can be attained and, hence, the efficiency of extracting light to the outside can effectively improved.

Here, preferably, in the transparent substrate, a plurality of scatterer layers are formed, and the plurality of scatterer layers are arranged in multiple stages to oppose to each other. By arranging the scatterer layers in multi-stages, it becomes possible to more efficiently scatter the light that has entered from the multi-layered structure to the transparent substrate.

More preferably, in the transparent substrate, the scatterer layers are formed in multiple stages, and the light scattering portions forming each of the scatterer layers are arranged not to overlap with the light scattering portions of scatterer layers of other stages. If the positions of light scattering portions of a scatterer layer are overlapped with the positions of light scattering portions of the scatterer layer of another stage when viewed two-dimensionally, the strength of the transparent substrate at the overlapping region decreases, and the transparent substrate tends to break easily. Therefore, by arranging the positions of light scattering portions of scatterer layer not to be overlapped with the positions of light scattering portions of the scatterer layer of another stage when viewed two-dimensionally as described above, decrease in strength of the transparent substrate can be prevented.

Each of the plurality of light scattering portions may have an approximately ellipsoidal shape extending in thickness direction of the transparent substrate.

More preferably, the semiconductor light emitting element further includes a transparent electrode layer formed on the multi-layered structure, and the plurality of light scattering portions are formed in a region immediately below the transparent electrode layer. A current is injected to the semiconductor multi-layered film through the light-transmitting electrode layer, and the region where the current is injected emits light. By forming a plurality of light scattering portions at the region immediately below the light-transmitting electrode layer, it becomes possible to scatter the light emitted from the multi-layered structure more effectively at the light scattering portions. Thus, it becomes easier to extract light from the side surface of transparent substrate.

If the semiconductor light emitting element includes a metal electrode layer formed to overlap with the transparent electrode layer, the plurality of light scattering portions may be formed in a region immediately below the transparent electrode except for a region immediately below the metal electrode layer. At the region immediately below the metal electrode layer, not much light is incident on the transparent substrate at an angle at which it is difficult to take out the light from the side surface of transparent substrate. Therefore, even when the light scattering portions are not formed in the region immediately below the metal electrode layer, the efficiency of extracting light to the outside can be improved.

More preferably, the transparent substrate is thicker than 10 μm, and each of the plurality of light scattering portions is formed at a position apart by a distance of at least 10 μm in thickness direction from a surface on which the multi-layered structure is formed, of the transparent substrate. By forming the plurality of light scattering portions at such positions, the light scattering effect attained by the light scattering portions can easily be improved.

At least some of the plurality of light scattering portions may be arranged in a line.

Here, preferably, direction of extension of the light scattering portions arranged in a line intersects a cleavage plane of the transparent substrate. When the light scattering portions are arranged as lines parallel to the cleavage plane, the transparent substrate tends to break easily at those portions. By way of example, when a semiconductor wafer is divided into individual semiconductor light emitting elements (chip dicing), it becomes more likely that the wafer is divided at positions different from the intended dividing positions. By arranging the light scattering portions at positions intersecting the cleavage plane of transparent substrate, the problem of division at positions different from intended dividing position can be prevented. Thus, yield of division at the time of chip dicing can be improved.

More preferably, the light scattering portion is formed of a heat denatured region. The heat denatured region can be formed, for example, by laser beam irradiation. By forming the light scattering portion using the heat denatured region, it is possible to form the light scattering portion easily in the transparent substrate, since the heat denatured region comes to have a refractive index different from the surrounding substrate. Further, if the heat denatured region comes to be a cavity, the inside of cavity will be vacuum (having refractive index of 1) and, therefore, the difference in refractive index from the transparent substrate increases. Thus, higher effect of light scattering can be attained at the light scattering portions.

More preferably, on a side surface portion of the transparent substrate, a processed portion processed by laser irradiation and used as a start point for dividing the transparent substrate is formed, and in the transparent substrate, position of the scatterer layer in the thickness direction is different from the position of the processed portion in the thickness direction. The processed portion that will be a starting point of dividing at the time of chip dicing is processed by laser irradiation. By forming the scatterer layer at a position different from the processed portion in the thickness direction of transparent substrate, division in an unintended direction can be prevented. Thus, yield of dividing at the time of chip dicing can further be improved.

More preferably, the transparent substrate is any of a sapphire substrate, a nitride semiconductor substrate, a SiC substrate and a quartz substrate.

According to a second aspect, the present invention provides a method of manufacturing a semiconductor light emitting element, including the steps of: forming a multi-layered structure including a semiconductor multi-layered film on one surface of a substrate; removing the other surface of the substrate not having the multi-layered structure formed thereon until the substrate reaches a prescribed thickness; directing a laser beam from the side of the other surface to the inside of the substrate and thereby forming, in the substrate, a light scattering portion scattering light that has entered the substrate; and dividing the substrate to individual semiconductor light emitting elements.

After forming the multi-layered structure on one surface of the substrate, the other surface of the substrate on which the multi-layered structure is not formed is removed and thereby the thickness of substrate is reduced to a prescribed thickness. From the side of this surface reduced to the desired thickness, a laser beam is directed to the inside of the substrate. The heat denatured region is formed inside the substrate by the laser beam irradiation, and the heat denatured region forms the light scattering portion. Specifically, the light scattering portions are formed inside the substrate by irradiating the inside of substrate with the laser beam. By dividing the substrate having the light scattering portions formed therein, semiconductor light emitting elements are provided. In the substrate of the thus obtained semiconductor light emitting element, the light scattering portions are formed. The light scattering portions scatter light that entered the substrate. On one surface of the substrate, the multi-layered structure including the semiconductor multi-layered film is formed and the light emitted by the multi-layered structure enters the substrate. The light scattering portions scatter the light that has entered the substrate from the multi-layered structure, and make it easier to extract light from the side surface of substrate. Thus, the efficiency of extracting light to the outside can be improved.

No matter whether the semiconductor light emitting element is sealed by a transparent resin having the refractive index of about 1.4 to about 1.5, it is possible to extract light that has entered the substrate from the side surface of the substrate with high efficiency, because of the light scattering portions. Further, since the light scattering portions are formed inside the substrate, decrease in the light scattering effect can be prevented even when the light emitting element is mounted on a stem or the like using a die bonding paste formed of transparent silicone resin having the refractive index of about 1.5. Therefore, by manufacturing the semiconductor light emitting element in accordance with the manufacturing method of the present invention, the resulting semiconductor light emitting element can improve the efficiency of extracting light to the outside, even in the mounted state.

Here, assume that the laser beam is directed to the inside of substrate from the surface on which the multi-layered structure is formed. In that case, the laser beam would pass through the multi-layered structure including the semiconductor multi-layered film and, therefore, characteristics of the element may be undesirably affected. Further, if an electrode is formed on the multi-layered structure, the laser beam would be blocked by the electrode and it becomes difficult to form the light scattering portions below the portion where the electrode is formed.

According to the present manufacturing method, the laser beam is directed to the inside of substrate from the other surface on which the multi-layered structure is not formed, to form the light scattering portions. Therefore, the laser beam does not pass through the multi-layered structure when the light scattering portions are formed. Thus, degradation of element characteristics caused by the laser beam passing the multi-layered structure can be prevented. Even when an electrode, for example, is formed on the multi-layered structure, the light scattering portions can be formed inside the substrate, since the laser beam is introduced from the side opposite to the side where the electrode is formed.

Preferably, the step of forming the light scattering portion includes the step of forming the light scattering portion close to the other surface of the substrate.

By forming the light scattering portions close to the other surface of the substrate, the light scattering portions come to be formed away from the semiconductor multi-layered film. Since the temperature near the point of focus of a laser beam tends to be high, the influence of heat to the semiconductor multi-layered film can be reduced by forming the light scattering portions at positions away from the semiconductor multi-layered film. Thus, thermal deterioration and alteration of semiconductor multi-layered film caused by the heat at the time of laser irradiation can be prevented. Further, by forming the light scattering portions close to the other surface of the substrate, it becomes possible to directly use the light extracted from the side surface of substrate, of the light emitted from the multi-layered structure to the substrate, in the semiconductor light emitting element.

More preferably, the step of forming the light scattering portion close to the other surface includes the step of forming the light scattering portion closer to the other surface than an intermediate position between the one surface and the other surface in the thickness direction of the substrate.

Accordingly, the influence of heat on the semiconductor multi-layered film can easily be reduced. Further, a semiconductor light emitting element allowing direct use of light extracted from the side surface of substrate of the light emitted from the multi-layered structure to the substrate can be manufactured easily.

According to a third aspect, the present invention provides a method of manufacturing a semiconductor light emitting element, including the steps of: directing a laser beam from the side of one surface of a substrate and thereby forming, in the substrate, a light scattering portion scattering light that has entered the substrate; forming a multi-layered structure including a semiconductor multi-layered film on the substrate; removing a surface of the substrate not having the multi-layered structure formed thereon until the substrate reaches a prescribed thickness; and dividing the substrate to individual semiconductor light emitting elements.

The light scattering portions are formed by laser beam irradiation from one surface of the substrate. Using the substrate having the light scattering portions thus formed, a multi-layered structure including a semiconductor multi-layered film is formed on the substrate. After forming the multi-layered structure, that surface of the substrate on which the multi-layered structure is not formed is removed until the substrate is reduced to a prescribed thickness. By dividing the substrate, semiconductor light emitting elements are obtained.

In the substrate of the thus obtained semiconductor light emitting device, light scattering portions are formed. The light scattering portions scatter light that has entered the substrate. On one surface of the substrate, the multi-layered structure including the semiconductor multi-layered film is formed, and the light emitted from the multi-layered structure enters the substrate. The light scattering portions scatter the light that has entered the substrate from the multi-layered structure, and make it easier to extract light from the side surface of substrate. Thus, the efficiency of extracting light to the outside is improved. By manufacturing the semiconductor light emitting element in accordance with the present method, the resulting semiconductor light emitting element can improve the efficiency of extracting light to the outside even in a mounted state.

Further, according to the present manufacturing method, since the light scattering portions are formed inside the substrate before forming the multi-layered structure, the semiconductor multi-layered film is free from the influence of heat generated by laser irradiation. Thus, it is possible to freely select the positions to form the light scattering portions, considering, for example, the intended use of the semiconductor light emitting element.

Preferably, the step of forming the light scattering portion includes the step of forming the light scattering portion close to a surface of the substrate having the multi-layered structure formed thereon.

After forming the light scattering portions close to that surface of the substrate on which the multi-layered structure is to be formed, the multi-layered structure is formed. Thus, the light scattering portions can be formed close to the multi-layered structure. According to the present manufacturing method, the multi-layered structure is formed after the light scattering portions are formed. Therefore, even when the light scattering portions are to be formed near the multi-layered structure, the semiconductor multi-layered film is not affected by the heat generated by laser irradiation. As a result, the light scattering portions can be formed near the multi-layered structure while the degradation of element characteristics caused by heat can be prevented. Since the light scattering portions are formed near the multi-layered structure, a semiconductor light emitting element having high axial light intensity (with light traveling to the lateral direction reduced) can be manufactured easily.

More preferably, with the surface of the substrate having the multi-layered structure formed thereon being one surface and the surface of the substrate opposite to the surface having the multi-layered structure formed thereon being the other surface, the step of forming the light scattering portion includes the step of forming the light scattering portion on the side closer to the other surface than an intermediate position between the one surface and the other surface in the thickness direction of the substrate.

Thus, a semiconductor light emitting element allowing direct use of light extracted from the side surface of substrate, of the light emitted from the multi-layered structure to the substrate, can be manufactured easily, while the influence of heat on the semiconductor multi-layered film is effectively reduced.

More preferably, the step of removing includes the step of removing the other surface of the substrate so that the light scattering portion is provided close to the other surface of the substrate.

Thus, it is possible to easily form the light scattering portions close to the other surface of the substrate. By forming the light scattering portions close to the other surface of the substrate, it becomes easier to directly use the light extracted from the side surface of the substrate, of the light emitted from the multi-layered structure to the substrate.

More preferably, the step of forming the light scattering portion includes the step of directing a laser beam from the side of the surface of the substrate having the multi-layered structure formed thereon.

Thus, the light scattering portions can easily be formed close to the multi-layered structure.

According to a fourth aspect, the present invention provides a semiconductor light emitting device, including: a semiconductor light emitting element; and a mounting portion for mounting the semiconductor light emitting element. The semiconductor light emitting element includes a substrate and a multi-layered structure including a semiconductor multi-layered film formed on the substrate. A light scattering portion scattering light that entered the substrate is formed inside the substrate.

The light scattering portions scatter the light from the multi-layered structure that has entered the substrate, and thereby improves the efficiency of light extraction of semiconductor light emitting element. By mounting such a semiconductor light emitting element, a semiconductor light emitting device having high efficiency of extracting light to the outside can be obtained.

In the semiconductor light emitting device in accordance with the present invention, since the light scattering portions are formed in the substrate of semiconductor light emitting element, the efficiency of extracting light to the outside can be improved without using a material having high reflection/scattering characteristics at the mounting portion where the semiconductor light emitting element is mounted. Therefore, degree of freedom in designing the semiconductor light emitting device can be improved. By way of example, it is possible not to use any material having high reflection/scattering characteristics at the mounting portion. Such an approach reduces manufacturing cost.

More preferably, the mounting portion is formed of a heat radiator radiating heat from the semiconductor light emitting element. Since the heat radiating characteristic of the semiconductor light emitting device can be improved, decrease in illuminance caused by the heat generated when the semiconductor light emitting device is driven can be prevented.

More preferably, the heat radiator is formed of a material containing at least one selected from the group consisting of Al, Ag, Au, Cu, Mo, W, Sn, C, SiC, AlN and Si.

By forming the heat radiator using such a material, a high heat radiator with high heat radiating characteristic can be formed. By forming the mounting portion using such a high heat radiator, the heat radiating characteristic of the semiconductor light emitting device can further be improved.

More preferably, the semiconductor light emitting device further includes a coupling layer formed of a metal material having low melting point, for coupling the semiconductor light emitting element to the mounting portion.

By coupling the semiconductor light emitting element to the mounting portion by means of a coupling layer formed of metal material of low melting point, the heat generated in the semiconductor light emitting element can effectively be transferred to the mounting portion. Thus, the heat generated in the semiconductor light emitting element can effectively be radiated from the mounting portion and, hence, the heat radiating characteristic of semiconductor light emitting device can further be improved. Since the light scattering portions are formed inside the substrate of semiconductor light emitting element, the efficiency of extracting light to the outside can be improved even when a coupling layer formed of metal material of low melting point is used as the coupling layer for coupling the semiconductor light emitting element to the mounting portion.

More preferably, the semiconductor light emitting device further includes: a wavelength converting portion for converting wavelength of light from the semiconductor light emitting element; and a reflection portion provided outside the wavelength converting portion, for reflecting light emitted from the semiconductor light emitting element.

By the light reflecting portion provided outside the wavelength converting portion, orientation of the light emitted from the semiconductor light emitting element and the light having its wavelength converted by the wavelength converting portion can be controlled and thereby the efficiency of light extraction can easily be improved.

Preferably, the wavelength converting portion contains at least one type of fluorescent substance.

According to a fifth aspect, the present invention provides a light transmitting substrate. The substrate includes a plurality of light scattering portions formed inside the substrate for scattering light that entered the substrate. The plurality of light scattering portions are dispersed in a plane in the substrate.

By forming a semiconductor light emitting element to include such a substrate, a semiconductor light emitting element having improved efficiency of extracting light to the outside can easily be obtained.

As can be seen from the foregoing, by the present invention, a semiconductor light emitting element that can improve the efficiency of extracting light to the outside even in the mounted state can easily be obtained. Further, by the present invention, a method of manufacturing a semiconductor light emitting element capable of improving the efficiency of extracting light to the outside even in the mounted state, a semiconductor light emitting device mounting such a semiconductor light emitting device and a substrate used for the semiconductor light emitting element can easily be obtained.

### BRIEF DESCRIPTION OF THE DRAWINGS

FIG. 1 is a cross-sectional view (along a line 1-1 of FIG. 2) of the semiconductor light emitting element in accordance with a first embodiment of the present invention.

FIG. 2 is a plan view of the semiconductor light emitting element shown in FIG. 1.

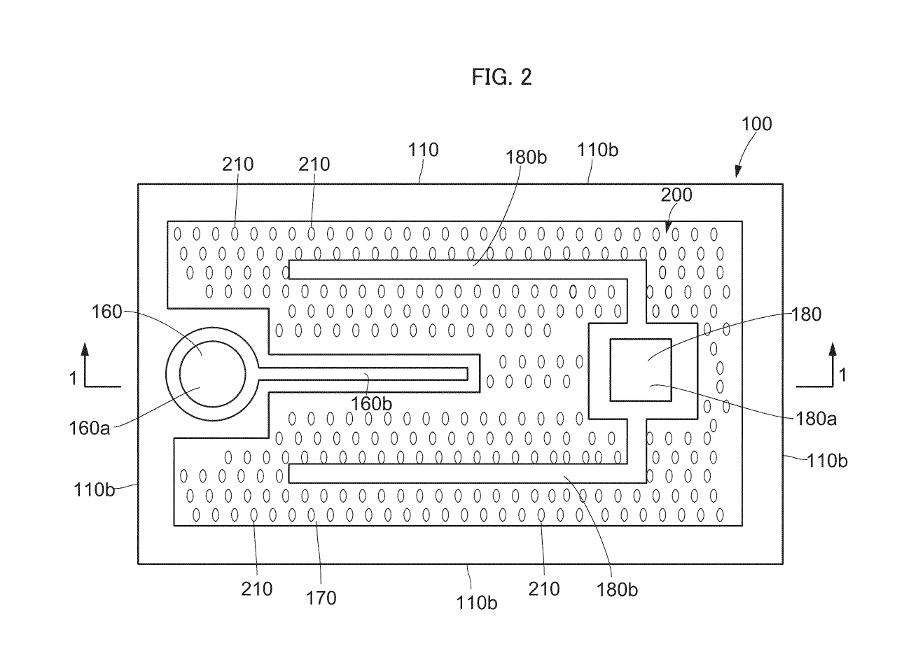

FIG. 3 includes a plan view 3A and a cross-sectional view 3B, illustrating a light scattering structure of the semiconductor light emitting element shown in FIG. 1.

FIG. 4 is a cross-sectional view of the semiconductor light emitting element in accordance with the first embodiment of the present invention.

FIG. 5 is a plan view illustrating the light scattering structure of the semiconductor light emitting element shown in FIG. 1.

FIG. 6 is a cross-sectional view along a line 6-6 of FIG. 5.

FIG. 7 is a cross-sectional view showing optical path of light that entered the transparent substrate, in the semiconductor light emitting element shown in FIG. 1.

FIG. 8 is a cross-sectional view showing optical path of light that entered the transparent substrate, when the light scattering structure is not formed in the transparent substrate.

FIG. 9 is a cross-sectional view illustrating the method of manufacturing the semiconductor light emitting element shown in FIG. 1.

FIG. 10 is a cross-sectional view illustrating the method of manufacturing the semiconductor light emitting element shown in FIG. 1.

FIG. 11 is a cross-sectional view illustrating the method of manufacturing the semiconductor light emitting element shown in FIG. 1.

FIG. 12 is a cross-sectional view illustrating the method of manufacturing the semiconductor light emitting element shown in FIG. 1.

FIG. 13 is a cross-sectional view illustrating the method of manufacturing the semiconductor light emitting element shown in FIG. 1.

FIG. 14 is a cross-sectional view illustrating the method of manufacturing the semiconductor light emitting element shown in FIG. 1.

FIG. 15 is a plan view illustrating the method of manufacturing the semiconductor light emitting element shown in FIG. 1.

FIG. 16 is a cross-sectional view illustrating the method of manufacturing the semiconductor light emitting element shown in FIG. 1.

FIG. 17 is a micrograph showing a state of light scattered by the light scattering structure.

FIG. 18 is a cross-sectional view of the semiconductor light emitting device in accordance with a second embodiment of the present invention.

FIG. 19 is a cross-sectional view schematically showing the semiconductor light emitting device of FIG. 18.

FIG. 20 is a cross-sectional view of a semiconductor light emitting device mounting a semiconductor light emitting element not having the light scattering portions formed therein.

FIG. 21 is a cross-sectional view of the semiconductor light emitting device in accordance with a third embodiment of the present invention.

FIG. 22 is a cross-sectional view of the semiconductor light emitting device in accordance with a fourth embodiment of the present invention.

FIG. 23 is a cross-sectional view of the semiconductor light emitting device in accordance with a fifth embodiment of the present invention.

FIG. 24 is a cross-sectional view illustrating the method of manufacturing the semiconductor light emitting element shown in FIG. 23.

FIG. 25 is a cross-sectional view illustrating the method of manufacturing the semiconductor light emitting element shown in FIG. 23.

FIG. 26 is a cross-sectional view illustrating the method of manufacturing the semiconductor light emitting element shown in FIG. 23.

FIG. 27 is a cross-sectional view illustrating the method of manufacturing the semiconductor light emitting element shown in FIG. 23.

FIG. 28 is a cross-sectional view illustrating the manufacturing method in which the light scattering portions are formed close to the multi-layered structure after forming the multi-layered structure.

FIG. 29 is a cross-sectional view illustrating the method of manufacturing the semiconductor light emitting element in accordance with a sixth embodiment of the present invention.

FIG. 30 is a cross-sectional view illustrating the method of manufacturing the semiconductor light emitting element in accordance with a sixth embodiment of the present invention.

FIG. 31 is a cross-sectional view illustrating the method of manufacturing the semiconductor light emitting element in accordance with a sixth embodiment of the present invention.

FIG. 32 is a cross-sectional view illustrating the method of manufacturing the semiconductor light emitting element in accordance with a sixth embodiment of the present invention.

FIG. 33 is a cross-sectional view of a semiconductor light emitting element in accordance with a tenth embodiment of the present invention.

FIG. 34 is a cross-sectional view of a semiconductor light emitting element in accordance with an eleventh embodiment of the present invention.

FIG. 35 is an illustration of the light scattering structure of a semiconductor light emitting element in accordance with a thirteenth embodiment of the present invention.

FIG. 36 is an illustration of the light scattering structure of a semiconductor light emitting element in accordance with a fourteenth embodiment of the present invention.

FIG. 37 is a cross-sectional view along a line 37-37 of FIG. 36.

FIG. 38 is a cross-sectional view of a semiconductor light emitting element in accordance with a fifteenth embodiment of the present invention.

FIG. 39 includes a plan view 39A and a cross-sectional view 39B, illustrating a light scattering structure of a semiconductor light emitting element in accordance with a modification of the present invention.

FIG. 40 includes a plan view 40A and a cross-sectional view 40B, illustrating a light scattering structure of a semiconductor light emitting element in accordance with another modification of the present invention.

FIG. 41 includes a plan view 41A and a cross-sectional view 41B, illustrating a light scattering structure of a semiconductor light emitting element in accordance with another modification of the present invention.

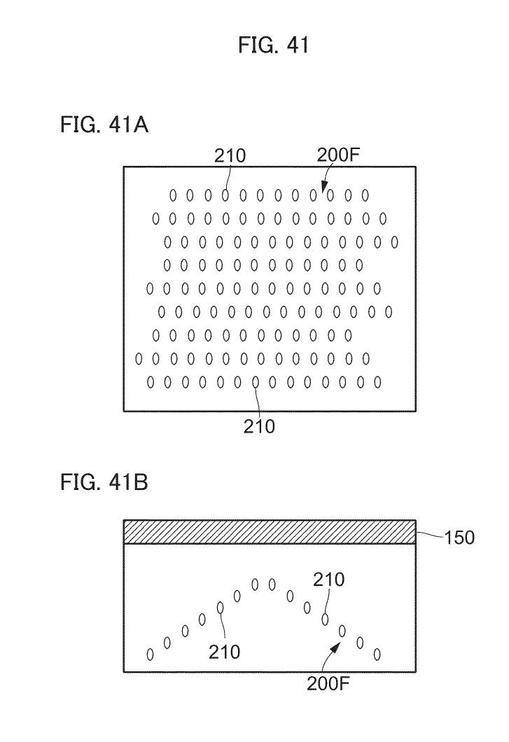

FIG. 42 includes a plan view 42A and a cross-sectional view 42B, illustrating a light scattering structure of a semiconductor light emitting element in accordance with another modification of the present invention.

FIG. 43 includes a plan view 43A and a cross-sectional view 43B, illustrating a light scattering structure of a semiconductor light emitting element in accordance with another modification of the present invention.

FIG. 44 is a cross-sectional view illustrating a semiconductor light emitting element in accordance with another modification of the present invention.

### DETAILED DESCRIPTION OF THE INVENTION

In the following, embodiments implementing the present invention will be described in detail with reference to the figures. In the following description and in the drawings, the same parts and components will be denoted by the same reference characters and names. Their functions are also the same. Therefore, detailed description thereof will not be repeated.

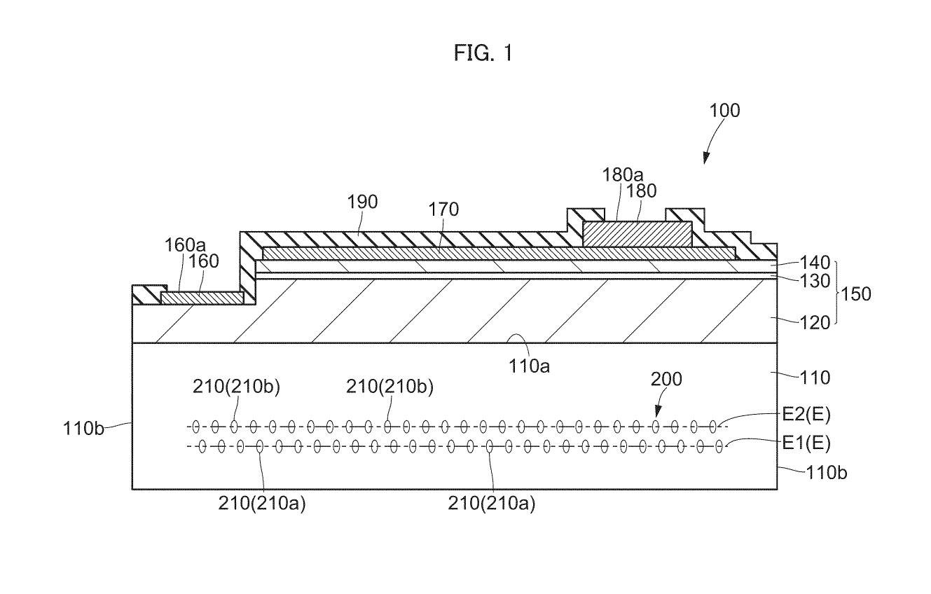

Referring to FIG. 1, a semiconductor light emitting element 100 in accordance with the present embodiment is implemented by a light emitting diode (LED) formed by using a nitride semiconductor. Semiconductor light emitting element 100 includes a transparent substrate 110 that transmits light emitted from the element itself. Transparent substrate 110 has a main surface 110a and a side surface 110b. On the main surface 110a of transparent substrate 110, a multi-layered structure 150 including a semiconductor multi-layered film is formed. Multi-layered structure 150 includes an n-type layer 120, an MQW light emitting layer 130 having a MQW (Multiple Quantum Well) structure, and a p-type layer 140.

In the present embodiment, a sapphire substrate is used as transparent substrate 110. The thickness of transparent substrate 110 is, for example, 120 μm. Inside the transparent substrate 110, a light scattering structure 200 for scattering light emitted from MQW light emitting layer 130 is provided. The light scattering structure 200 is realized by a region having a refractive index different from the refractive index (1.78) of transparent material (in the present embodiment, sapphire), and because of the difference in refractive index from transparent substrate 110, it scatters the light that has entered the inside of substrate. Details of light scattering structure 200 will be described later.

The n-type layer 120 is provided on main surface 110a of transparent substrate 110, constituted by a buffer layer, an underlying layer, an n-type nitride semiconductor layer, a low-temperature n-type GaN/InGaN multi-layered structure and a super-lattice layer as an intermediate layer (all not shown) formed in this order from the side of main surface 110a. In the present specification, the super-lattice layer means a layer having very thin crystal layers stacked with each other so as to have a periodic structure of crystal lattice longer than the primitive unit lattice. The p-type layer 140 is constituted by a p-type AlGaN layer, a p-type GaN layer and a high-concentration p-type GaN layer (all not shown) formed in this order from the side of MQW light emitting layer 130, on MQW light emitting layer 130.

The buffer layer is formed, for example, of Alₛ₀Gaₜ₀N (0≦s0≦1, 0≦t0≦1, s0+t0≠0). Preferably, the buffer layer is formed of an AlN layer or a GaN layer. Only a small part (for example, about 0.5% to about 2%) of N (nitrogen) may be replaced by O (oxygen). By this approach, the buffer layer comes to be formed to extend along the normal direction of main surface 110a of transparent substrate 110 and, therefore, a buffer layer formed of a set of columnar crystals with uniform crystal grains can be obtained. Though not specifically limiting, the thickness of buffer layer is preferably at least 3 nm and at most 100 nm, and more preferably, at least 5 nm and at most 50 nm.

The underlying layer is formed, for example, of Alₛ₁Gaₜ₁Inᵤ₁N (0≦s1≦1, 0≦t1≦1, 0≦u1≦1, s1+t1+u1≠0). Preferably, the underlying layer is formed of Alₛ₁Gaₜ₁N (0≦s1≦1, 0≦t1≦1, s1+t1≠1) and, more preferably, it is formed of a GaN layer. Preferable thickness of underlying layer is at least 1 μm and at most 8 μm.

The n-type nitride semiconductor layer is formed, for example, of Alₛ₂Gaₜ₂Inᵤ₂N (0≦s2≦1, 0≦t2≦1, 0≦u2≦1, s2+t2+u2≈1), doped with an n-type impurity. More preferably, the n-type nitride semiconductor layer is formed, for example, of Alₛ₂Ga₍₁₋ₛ₂₎N (0≦s2≦1, preferably, 0≦s2≦0.5, more preferably, 0≦s2≦0.1), doped with an n-type impurity. As the n-type impurity, Si is used. Though not specifically limited, the n-type doping concentration (different from carrier concentration) is preferably at most 1×10¹⁹ cm⁻³.

The low-temperature n-type GaN/InGaN multi-layered structure has a function of relaxing stress to MQW light emitting layer 130 from transparent substrate 110 and the underlying layer. The low-temperature n-type GaN/InGaN multi-layered structure is constituted by an n-type InGaN layer of about 7 nm in thickness, an n-type GaN layer of about 30 nm in thickness, an n-type InGaN layer of about 7 nm in thickness and an n-type GaN layer of about 20 nm in thickness stacked on each other.

The super-lattice layer has a super-lattice structure having wide-gap and narrow-gap layers stacked one after another. The periodic structure thereof is longer than the primitive unit lattice of the semiconductor material forming the wide band gap layer and longer than the primitive unit lattice of the semiconductor material forming the narrow band gap layer. The length of one period of super-lattice layer (total thickness of the thickness of wide band gap layers and thickness of narrow band gap layers) is shorter than the length of one period of MQW light emitting layer 130. Specific thickness of super-lattice layer is, for example, at least 1 nm and at most 10 nm. Each wide band gap layer is formed, for example, of AlₐGa_{b}In_{(1-a-b)}N (0≦a<1, 0<b≦1). Each wide band gap layer is preferably formed of a GaN layer. Each narrow band gap layer is preferably formed of a semiconductor material having a band gap smaller than the wide band gap layer and larger than each well layer (not shown) of MQW light emitting layer 130. Each narrow band gap layer is formed, for example, of AlₐGa_{b}In_{(1-a-b)}N (0≦a<1, 0<b≦1). Preferably, each narrow band gap layer is formed of Ga_{b}In_{(1-b)}N (0<b≦1). If the wide band gap layer and the narrow band gap layer are both undoped, driving voltage increases. Therefore, it is preferred that at least one of the wide band gap layer and the narrow band gap layer is doped with an n-type impurity.

MQW light emitting layer 130 has a multi-quantum well structure having barrier layers and well layers (both not shown) stacked one after another. The length of one period (total thickness of barrier layer thickness and well layer thickness) of MQW light emitting layer 130 is, for example, at least 5 nm and at most 100 nm. The composition of each well layer is adjusted in accordance with the wavelength of light required of the semiconductor light emitting element. By way of example, the composition of each well layer may be Al_{c}Ga_{d}In_{(1-c-d)}N (0≦c<1, 0<d≦1). It is preferred that the composition of each well layer is InₑGa₍₁₋ₑ₎N (0<e≦1), not including Al. Preferably, each well layer has the same composition. In that case, the light emitted by re-combination of electrons and holes come to have the same wavelength in each well layer. This is preferred since it enables narrowing of light emission spectrum of the semiconductor light emitting device. Preferable thickness of each well layer is at least 1 nm and at most 7 nm.

Each barrier layer preferably has a band gap energy larger than each well layer. The composition of each barrier layer may be Al_{f}Ga_{g}In_{(1-f-g)}N (0≦f<1, 0<g≦1). More preferably, the composition of each barrier layer is InₕGa₍₁₋ₕ₎N (0<h≦1) not containing Al, or Al_{f}Ga_{g}In_{(1-f-g)}N (0≦f<1, 0<g≦1) with the lattice constant made substantially the same as that of well layer. As to the thickness of each barrier layer, if the thickness becomes smaller, the driving voltage lowers, while the light emitting efficiency lowers if the thickness is too small. Therefore, preferable thickness of each barrier layer is at least 1 nm and at most 10 nm and, more preferably, at least 3 nm and at most 7 nm.

The well layer and the barrier layer are doped with n-type impurities. It is noted, however, that the well layer and the barrier layer may not be doped with n-type impurities.

The p-type layer 140 is formed, for example, of Alₛ₄Gaₜ₄Inᵤ₄N (0≦s4≦1, 0≦t4≦1, 0≦u4≦1, s4+t4+u4≠0), doped with a p-type impurity. Preferably, the p-type layer 140 is formed of Alₛ₄Ga₍₁₋ₛ₄₎N (0<s4≦0.4, preferably, 0.1≦s4≦0.3) doped with a p-type impurity. The carrier concentration of p-type layer 140 is preferably 1×10¹⁷ cm⁻³ or higher. Here, activity rate of p-type impurity is approximately 0.01 and, therefore, preferable p-type doping concentration (different from the carrier concentration) of p-type layer 140 is at least 1×10¹⁹ cm⁻³. Here, it is noted that the concentration of p-type doping may be lower than this in a layer closer to MQW light emitting layer 130 (for example, in p-type AlGaN layer). Though not specifically limited, the thickness of p-type layer 140 (total thickness of three layers) may be at least 50 nm and at most 1000 nm. If the p-type layer 140 is made thin, heating time for the growth thereof can be reduced and, hence, diffusion of p-type impurity to MQW light emitting layer 130 can be reduced.

The multi-layered structure 150 described above further includes an exposed portion where a part of n-type layer 120 is exposed, and a mesa portion as a region outside the exposed region.

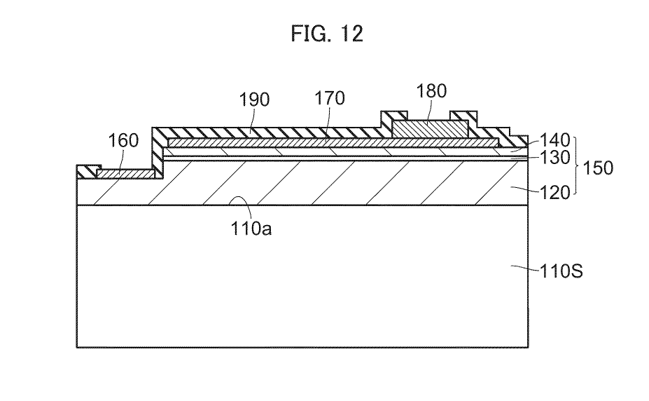

Referring to FIGS. 1 and 12, on an upper surface of exposed portion (on n-type layer 120), an n-side electrode 160 is formed. The n-side electrode 160 includes a pad portion 160a as a wire bonding region, and an elongate protruding portion (branch electrode: not shown) aimed to diffuse current, formed integrally with pad portion 160a. On an upper portion of mesa portion (on p-type layer 140), a p-side electrode 180 is formed with a transparent electrode (also referred to as a “light transmitting electrode”) 170 interposed. Transparent electrode 170 is formed over a relatively large area on the mesa portion. The p-side electrode 180 is formed on a partial region of transparent electrode 170. The p-side electrode 180 includes a pad portion 180a as a wire bonding region, and an elongate protruding portion (branch electrode: not shown) aimed to diffuse current, formed integrally with pad portion 180a.

Referring to FIG. 1, n-side electrode 160 has a multi-layered structure including, for example, a titanium layer, an aluminum layer and a gold layer stacked in this order on n-type layer 120. The thickness of n-side electrode 160 is, for example, about 1 μm. Considering the strength at the time of wire bonding, n-side electrode 160 may have a thickness of about 1 μm.

Transparent electrode 170 is formed, for example, of ITO (Indium Tin Oxide). Its thickness is, for example, at least 20 nm and at most 200 nm.

The p-side electrode 180 has a multi-layered structure including, for example, a nickel layer, an aluminum layer, a titanium layer and a gold layer, stacked in this order on transparent electrode 170. The thickness of p-side electrode 180 is, for example, about 1 μm. Again considering the strength at the time of wire bonding, p-side electrode 180 may also have a thickness of about 1 μm.

On the upper surface of semiconductor light emitting element 100, an insulating transparent protective film 190 of SiO₂ is formed. This transparent protective film 190 is formed to cover substantially the whole upper surface of semiconductor light emitting element 100. It is noted, however, that transparent protective film 190 is patterned to expose pad portion 180a of p-side electrode 180 and pad portion 160a of n-side electrode 160.

Processed portions, which will be described later, formed when a wafer was divided into individual chips (semiconductor light emitting elements) remain on a side surface 110b of transparent substrate 110.

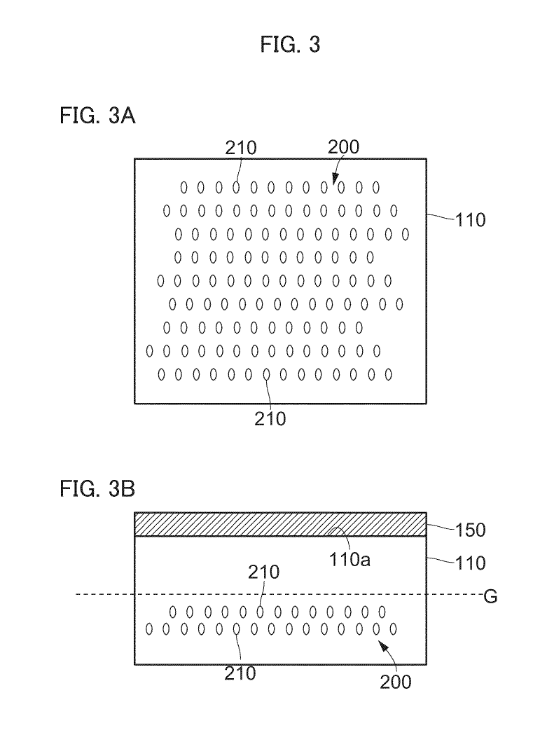

Referring to FIG. 3, light scattering structure 200 is implemented by a plurality of light scattering portions 210 formed in transparent substrate 110. Light scattering portions 210 are small regions that scatter light that has entered transparent substrate 110. The light scattering portions 210 are heat denatured regions formed by heating local regions of transparent substrate 110 by laser beam irradiation. When transparent substrate 110 is irradiated with laser beam, by multiphoton absorption of atoms existing in the irradiated region, the region is locally heated and crystal structure and crystal properties are altered with respect to surrounding regions, whereby a region having refractive index different from the surroundings is formed.

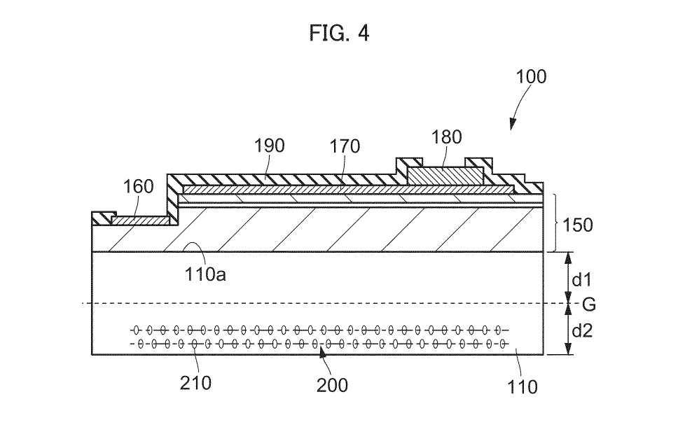

The plurality of light scattering portions 210 are dispersed in a plane in transparent substrate 110. Referring to FIGS. 3(B) and 4, the plurality of light scattering portions 210 are formed in a region closer to the back surface side than an intermediate position between main surface 110a and the back surface as an opposite surface to main surface 110a of transparent substrate 110. Assuming that the transparent substrate 110 is substantially equally divided into two in the thickness direction and two regions result, the plurality of light scattering portions 210 are formed on the region opposite to the multi-layered structure 150. In FIGS. 3(B) and 4, the intermediate position mentioned above is indicated by a dotted line G. At the intermediate position, the distance d1 in the thickness direction from dotted line G to main surface 110a is substantially equal to the distance d2 from the dotted line G to the back surface (d1≈d2). Here, it is preferred that the plurality of light scattering portions are formed near the back surface of transparent substrate 110.

Again referring to FIG. 1, in the present embodiment, the plurality of light scattering portions 210 are divided into a plurality of groups, with the distance from scattering portions in each group to the main surface 110a of transparent substrate 110 (distance in the thickness direction) is substantially the same. In other words, the plurality of light scattering portions 210 are dispersed in layers, at positions of substantially the same distances from the main surface 110a (upper surface) of transparent substrate 110. Since the plurality of light scattering portions 210 are dispersed in a plane in this manner, a scatterer layer E, which is a layer along a virtual plane, is formed inside transparent substrate 110.

Since the plurality of light scattering portions 210 are divided into a plurality of groups (two in the present embodiment) in accordance with the distance from the main surface 110a of transparent substrate 110 (distance in the thickness direction), it follows that scatterer layers E are provided in a plurality of stages (two in the present embodiment) spaced apart by a prescribed distance from each other. The plurality of scatterer layers E1 and E2 formed as a plurality of stages are arranged in transparent substrate 110 to be opposite to each other. These scatterer layers E1 and E2 are also arranged to be opposite to the main surface 110a of transparent substrate 110.

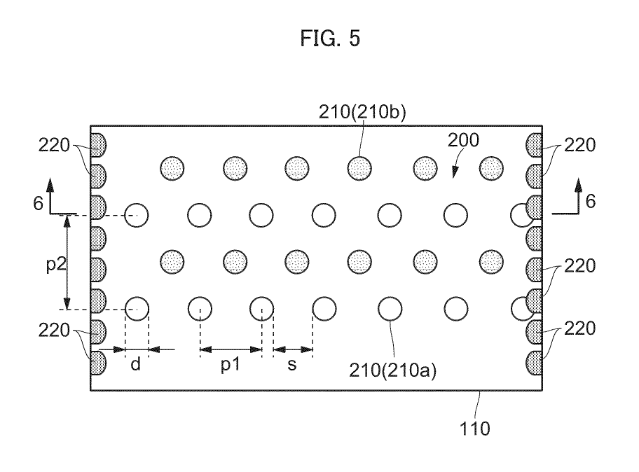

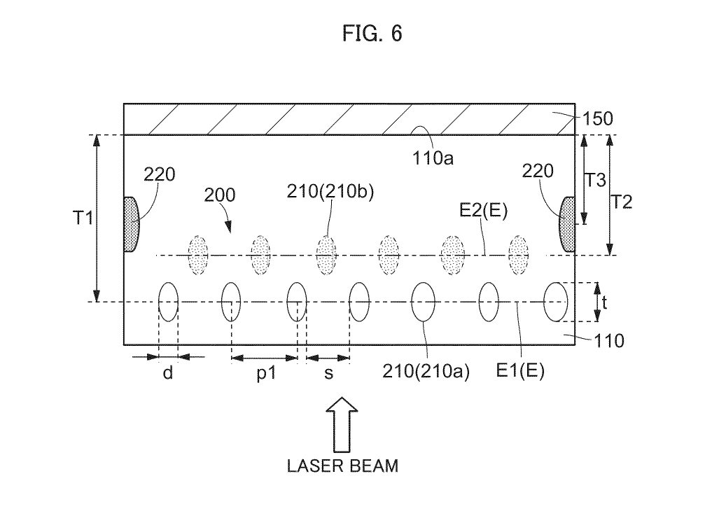

Referring to FIGS. 5 and 6, light scattering portions 210 forming the scatterer layer E of each stage are arranged not to be overlapped with the light scattering portions of layer E of other stages when viewed two-dimensionally (when semiconductor light emitting element 100 is viewed from above). Specifically, light scattering portions 210 of each stage are shifted in two-dimensional positions from the light scattering portions of other stages. By arranging the scatterer layers in multiple stages and by shifting the positions of light scattering portions of each stage to be different from other stages, the area where light scattering portions 210 exist can be made wider when viewed two dimensionally. This improves the effect of light scattering attained by light scattering structure 200, and high effect of light extraction can be attained.

Each of light scattering portions 210 is formed at a position apart by at least 10 μm in thickness direction from the main surface 110a (upper surface) of transparent substrate 110. The scatterer layers E in multiple stages will be referred to the first stage scatterer layer E1 and the second stage scatterer layer E2, in this order starting from the back surface side of transparent substrate. Each of light scattering portions 210a of the first stage scatterer layer E1 is formed at a position apart by a distance T1 (about 100 μm) in the thickness direction from the main surface 110a (upper surface) of transparent substrate 110. Each of light scattering portions 210b of the second stage scatterer layer E2 is formed at a position apart by a distance T2 (about 90 μm) in the thickness direction from the main surface 110a (upper surface) of transparent substrate 110. The distances T1 and T2 each represent the distance from the top surface of transparent substrate 110 to the center of light scattering portion 210 in the thickness direction. Further, in FIGS. 5 and 6, light scattering portions 210b forming the second stage scatterer layer E2 are hatched.

Each of the plurality of light scattering portions 210 is formed in an approximately ellipsoidal shape extending in the thickness direction of transparent substrate 110. The width d of light scattering portion 210 is, for example, about 2 μm, and height t (height t in thickness direction of transparent substrate 110) of light scattering portion 210 is about 7 μm. Light scattering portions 210 in each stage are arranged, for example, in a lattice, with a pitch p1 in one direction being about 6 μm and a pitch p2 in the other direction orthogonal to the one direction being, for example, about 8 μm.

Light scattering structure 200 formed as described above reflects light from MQW light emitting layer 130 that has entered from the upper surface of transparent substrate 110 to the inside of substrate, and makes it easier to take out the light from side surface 110b of transparent substrate 110 to the outside. Specifically, light scattering structure 200 reflects the light such that the incident angle of light to the side surface 110b of transparent substrate 110 becomes smaller.

The above-described processed portions 220 are formed at side surface 110b of transparent substrate 110. Processed portions 220 are processed by irradiating transparent substrate 110 with laser beams, in the similar manner as light scattering portions 210, and these are used as starting points for dividing the wafer into individual chips (semiconductor light emitting elements). Therefore, processed portions 220 are formed as straight lines along side surface 110b of transparent substrate 110. Processed portions 220 are formed at positions spaced by T3 (about 80 μm) in thickness direction from main surface 110a (upper surface) of transparent substrate 110. The distance T3 represents the distance from the top surface of transparent substrate 110 to the center of processed portion 220 in the thickness direction.

The processed portions 220 as described above are formed at positions shifted in thickness direction of transparent substrate 110 with respect to positions where light scattering portions 210 are formed. Here, it is preferred that processed portions 220 are formed at positions shifted by at least 4 μm in the thickness direction of transparent substrate 110 from light scattering portions 210b.

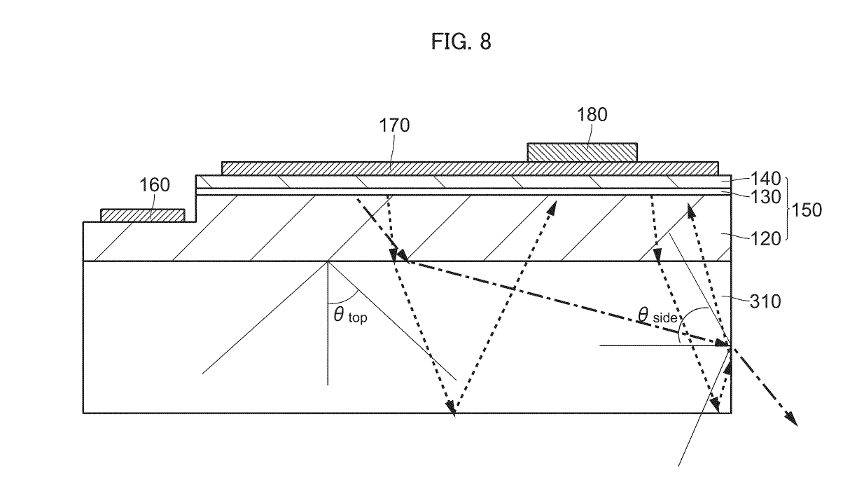

Referring to FIG. 8, when the light scattering structure is not formed in sapphire substrate 310, the light emitted downward from the active layer (light emitting layer 130) enters sapphire substrate 310, reflected by the substrate back surface and returns upward (toward the upper surface) through sapphire substrate 310. Further, part of the light that entered sapphire substrate 310 is emitted to the side surface of sapphire substrate 310. The semiconductor light emitting element is typically sealed with a transparent resin having the refractive index of about 1.4 to about 1.5. By way of example, when the semiconductor light emitting element is sealed with a transparent resin having the refractive index of 1.5, at an interface between the side surface of sapphire substrate 310 (refractive index=1.78) and the transparent resin, the angle of total reflection will be θ_{side}≧57.43°. Specifically, assuming that mirror reflection occurs at the back surface of sapphire substrate 310, the light entering from the upper surface of sapphire substrate 310 at an angle of 0°≦θₜₒₚ≦32.57° will not be taken out from the side surface of sapphire substrate 310 but returns to multi-layered structure 150 formed on sapphire substrate 310.

On the other hand, the light having the incident angle of θₜₒₚ>32.57° is divided to light directed to the side surface of sapphire substrate 310 (see chain-dotted arrows) and light returned to multi-layered structure 150, depending on the position where the light enters sapphire substrate 310. Here, the light directed to the side surface of sapphire substrate 310 is taken out to the outside from the side surface of sapphire substrate 310.

As described above, if the back surface of sapphire substrate 310 is a mirror-surface, the light having the incident angle of 0°≦θₜₒₚ≦32.57° is not at all taken out from sapphire substrate 310, but returns to multi-layered structure 150. Part of the light that has returned to multi-layered structure 150 is taken to the outside of the chip (outside of the light emitting element), and another part is absorbed by various light absorbing bodies such as transparent electrode 170, p-side electrode 180 and active layer (re-absorption by light emitting layer 130). Therefore, the light extracting efficiency is improved when the light emitted from multi-layered structure 150 to the side of sapphire substrate 310 is extracted from the side surface of sapphire substrate 310 to the outside than when the light is returned to multi-layered structure 150.

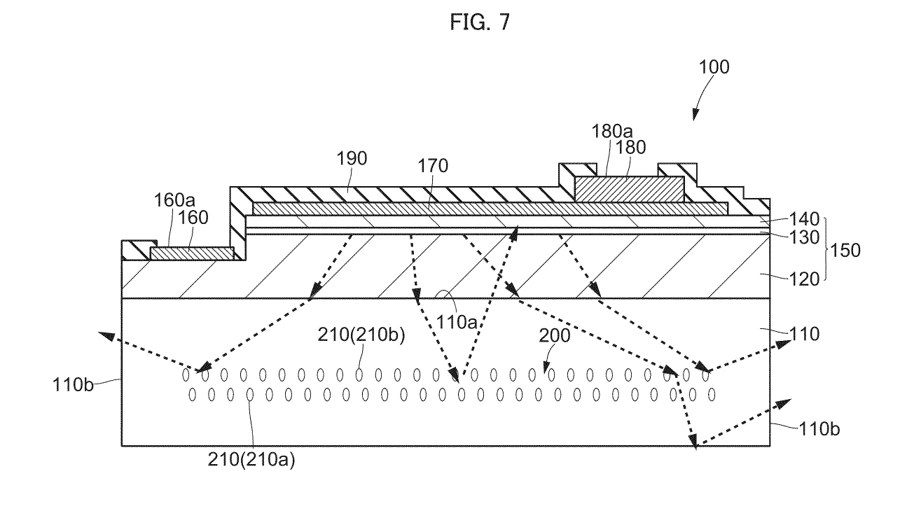

Referring to FIG. 7, in the present embodiment having light scattering structure 200 formed in transparent substrate 110, the light that entered transparent substrate 110 is scattered by light scattering structure 200, whereby the incident angle to the side surface 110b of transparent substrate 110 is made smaller. Even the light that has the incident angle of 0°≦θₜₒₚ≦32.57° is scattered by light scattering structure 200, and the incident angle to side surface 110b of transparent substrate 110 is changed. Consequently, at the interface between side surface 110b of transparent substrate 110 and the transparent resin, the incident angle becomes smaller than the angle of total reflection and, therefore, the light can be extracted with higher efficiency from the side surface of transparent substrate 110.

The amount of light having the incident angle of 0°≦θₜₒₚ≦32.57° is relatively small in the region immediately below p-side electrode 180. Therefore, even when light scattering portions 210 are not formed in the region immediately below p-side electrode 180, the efficiency of extracting light to the outside hardly decreases.

In order to extract light with high efficiency from side surface 110b of transparent substrate 110, it is preferred to have the light having the incident angle of 0°≦θₜₒₚ≦32.57° scattered by light scattering structure 200. By arranging the scatterer layers E in multiple stages and shifting the positions of light scattering portions of each stage from those of other stages, the area where the light scattering portions 210 exist can be made wider when viewed two-dimensionally. As a result, the light having the incident angle as small as 0°≦θₜₒₚ≦32.57° can be scattered with high efficiency by light scattering structure 200.

Referring to FIGS. 5, 6 and 10 to 16, the method of manufacturing semiconductor light emitting element 100 in accordance with the present embodiment will be described.

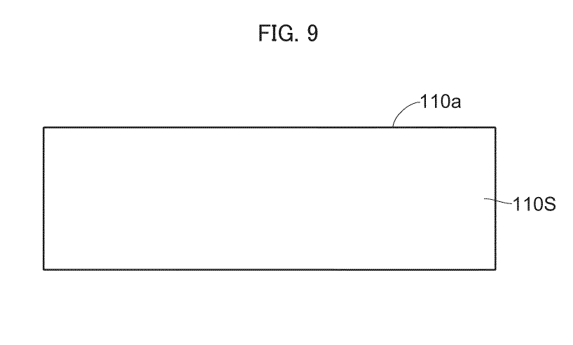

Referring to FIG. 9, first, a transparent substrate 110S of sapphire, having the thickness of about 400 μm to about 1300 μm is prepared. The main surface 110a (on which the nitride semiconductor layer is formed) of transparent substrate 110S is mirror-polished to have a mirror surface (with the surface roughness Ra of about 1 nm or smaller).

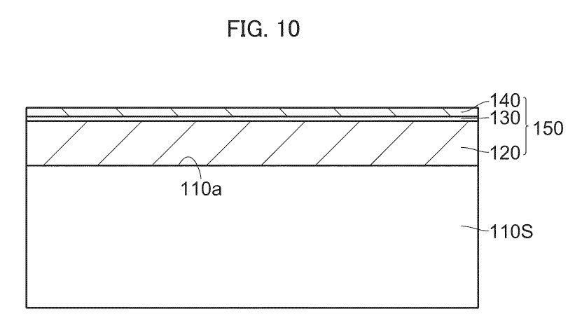

Thereafter, by using a vapor phase growth process such as MOCVD (Metal Organic Chemical Vapor Deposition), HVPE (Hydride Vapor Phase Epitaxy) and MBE (Molecular Beam Epitaxy), a multi-layered film of nitride semiconductor is formed on the main surface 110a of transparent substrate 110S. Specifically, referring to FIG. 10, on the main surface 110a of transparent substrate 110S, an n-type layer 120 consisting of a buffer layer, an underlying layer, an n-type nitride semiconductor layer, a low-temperature n-type GaN/InGaN multi-layered structure and a super-lattice layer, an MQW light emitting layer 130, and a p-type layer 140 are formed in this order. Thus, a multi-layered structure 150 including a multi-layered film is formed on the transparent substrate.

In the present embodiment, the heat denatured region as the light scattering structure 200 is formed below MQW light emitting layer 130 in the subsequent process step. Therefore, in order to prevent influence of heat, generated when the heat denatured region is to be formed, on MQW light emitting layer 130, a thick underlying layer is preferred. From this viewpoint, the underlying layer is preferably formed to have the thickness of at least 1 μm. Similar to the underlying layer, n-type nitride semiconductor layer should also be made thick, in order to prevent the influence of heat generated when the heat denatured region is to be formed on MQW light emitting layer 130. From this viewpoint, n-type nitride semiconductor layer is preferably formed such that the sum of thicknesses of underlying layer and n-type nitride semiconductor layer will be at least 2 μm.

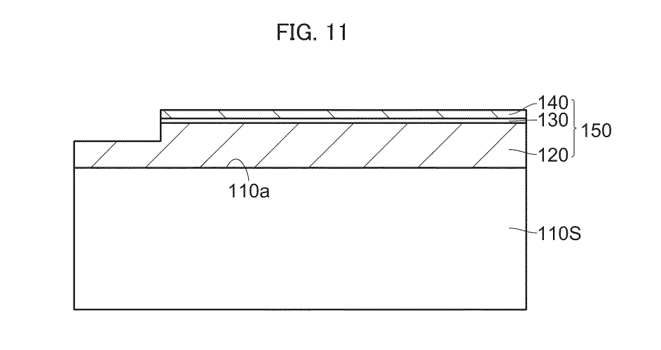

Thereafter, referring to FIG. 11, p-type layer 140, MQW light emitting layer 130 and n-type layer 120 are partially etched to expose a part of n-type layer 120. Referring to FIG. 12, on an upper surface of n-type layer 120 exposed by this etching, an n-side electrode 160 is formed. Further, on an upper surface of p-type layer 140, a transparent electrode 170 and a p-side electrode 180 are formed in this order. Thereafter, a transparent protective film 190 is formed to cover transparent electrode 170 and side surfaces of these layers exposed by the etching.

Next, the substrate with the electrodes formed is subjected to heat treatment, so that the electrodes are alloyed. This realizes satisfactory ohmic contact between the electrodes and the semiconductor layer and lowers contact resistance between the electrodes and the semiconductor layer. The temperature of heat treatment is preferably in the range of 200° C. to 1200° C., more preferably in the range of 300° C. to 900° C. and, further preferably, in the range of 450° C. to 650° C. As to other conditions of heat treatment, atmospheric gas should contain at least one of oxygen and nitrogen. It is also possible to conduct heat treatment in an atmosphere containing an inert gas such as Ar, or under atmospheric conditions.

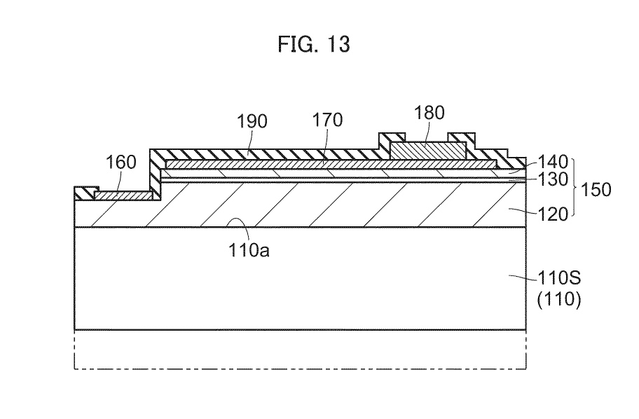

Next, as shown in FIG. 13, the wafer fabricated through the steps described above is ground and polished to reduce the thickness of transparent substrate 110S. Specifically, the wafer is set in a grinder and the back surface of the substrate 110S (on which the semiconductor layer is not formed) is ground and removed until the substrate thickness reaches about 160 μm. Next, the wafer is set in a polisher and the back surface of the substrate is polished with the count of abrasive agent changed stepwise to smaller ones until the back surface of transparent substrate 110S is made a mirror surface (optical mirror surface), and the substrate thickness is reduced to 120 μm. The substrate is mirror-finished in this manner, because any unevenness on the substrate surface may cause irregular cleavage and chipping, as the stress at the time of scribing (dicing) tends to be dispersed more easily. Preferably, the surface of the back surface after mirror-polishing has root-mean-square roughness Rq (old RMS) of at most 10 nm. By reducing the back surface of transparent substrate 110S to the prescribed thickness, transparent substrate 110 is obtained.

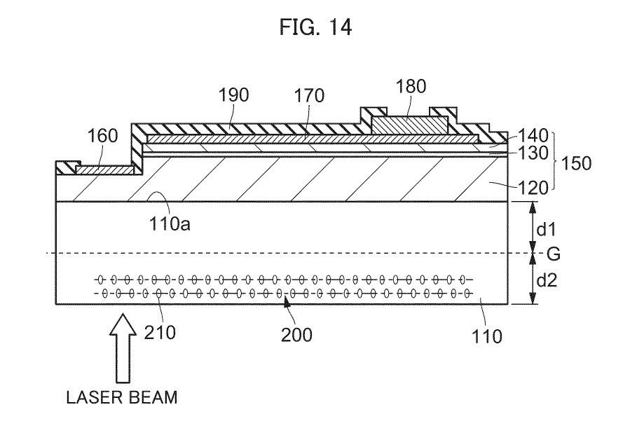

Referring to FIG. 14, after the substrate is reduced to the prescribed thickness, a plurality of light scattering portions 210 (light scattering structure 200) are formed in transparent substrate 110 using pulsed laser. In the following, for convenience, description will be made assuming that the spot diameter of laser beam is the same as the width d of light scattering portion 210.

For forming light scattering structure 200, various types of lasers can be used, including one generating pulsed laser beams, a continuous wave laser capable of causing multiphoton absorption and the like. Among others, lasers that generate pulsed laser beams such as femtosecond laser, picosecond laser and nanosecond laser are preferred. Though the wavelength is not specifically limited, various types including Nd:YAG laser, Nd:YVO₄ laser, Nd:YLF laser and titanium sapphire laser may be used. The laser wavelength is appropriately selected considering the light transmittance/light absorption derived from the material of substrate as the object of laser irradiation, the size and pattern precision of light scattering structure 200 formed in the substrate, practically usable laser device and the like.

If the laser wavelength is 200 nm to 350 nm, pulse width in the order of nano second (1 ns to 1000 ns) is preferred and 10 ns to 15 ns is more preferred. If the laser wavelength is 350 nm to 2000 nm, pulse width in the order of femto second to pico second (1 fs to 1000 ps) is preferred, and 200 fs to 800 fs is more preferred.

If the transparent substrate 110 is a sapphire substrate, the above-described irradiation conditions are available. Therefore, the above-described irradiation conditions are available in the present embodiment. Here, conditions other than the laser wavelength and the pulse width can be selected within the ranges below, from the viewpoint of practical usability and mass production capacity. Preferable conditions are as follows. Repetition frequency: 50 kHz to 500 kHz; laser power:0.05 W to 0.8 W; laser spot size; 0.5 μm to 4.0 μm (more preferably, around 2 μm); scanning speed of sample stage: 100 mm/s to 1000 mm/s. Formation is possible with the pulse energy in the range of 0.6 μJ to 12 μJ, the pulse energy density in the range of 40 J/cm² to 6 kJ/cm², and peak power density at a focal point in the range of 4×10¹³ W/cm² to 5×10¹⁵ W/cm².

The width d, height t and the position in the substrate of light scattering structure 200 (light scattering portion 210) can be adjusted by changing the conditions of laser irradiation. As shown in FIGS. 6 and 14, by directing a laser beam from the back surface side of transparent substrate 110 to the inside of substrate, light scattering structure 200 is formed.

Referring to FIGS. 5 and 6, from a laser beam irradiator, pulsed laser beams having repetition frequency X are collected and transparent substrate 110 is irradiated with the collected or focused light with the spot diameter d. Assuming that the scanning speed of sample stage (processing feed speed) is V, the spot pitch p1 between spots of pulsed laser beam will be the same or smaller than the spot diameter d of collected light if the value V/X is equal to or smaller than 1 d. Then, the collected spots will be in contact with each other or overlapped, realizing continuous irradiation. Thus, light scattering portions can be formed linearly. Further, by superposing lines, the light scattering portions can be formed as a plane.

In contrast, if the value V/X is larger than 2 d, the pitch between the formed light scattering portions will be larger than the spot diameter d of collected light, and spaces are formed between adjacent light scattering portions 210. A plurality of light scattering portions 210 are formed intermittently and linearly with spaces generated between each other. When V/X=2 d, the space s between adjacent light scattering portions 210 is equal to the spot diameter d and when V/X=5 d, the space s between adjacent light scattering portions 210 is four times the spot diameter d.

If the lines are to be formed on a plane with the pitch of p2, light scattering portions 210 are formed under the same laser irradiation conditions with the sample stage shifted by p2, and this operation is repeated. In this manner, a plurality of light scattering portions 210 can be formed (arranged) in a plane. Since light scattering portion 210 is formed at the point where the laser beams are collected, by changing the position of laser beam collection, positions (position of formation) of light scattering portions 210 in the thickness direction of transparent substrate 110 can be changed. Thus, the planes E with scattering structure can be formed in multi-stages (for example, in two or three stages).

By changing the scanning speed of sample stage and the repetition frequency of pulsed laser in this manner, the pitch of light scattering portions 210 can be changed. In addition, by changing the height of sample stage, the point of focus of laser beams can be changed and, hence, the light scattering portion 210 (heat denatured region) can be formed at an arbitrary position in the substrate (any desired position in the thickness direction of the substrate).

After forming the above-described light scattering structure 200 in transparent substrate 110, break lines (processed portions 220) used for dividing chips are formed in transparent substrate 110. The purpose for forming the break lines is different from that of light scattering structure 200, and the lines are formed linearly in transparent substrate 110 in order to divide into chips (semiconductor light emitting elements) of a prescribed size. The break lines (processed portions 220) can be formed by using a similar method as for the light scattering structure 200 (light scattering portions 210). Particularly, it is preferred to form the lines by irradiation with a laser beam that is transmitted through sapphire. Here, transmitted means that the transmittance is 70% or higher immediately after the transparent substrate 110 (sapphire substrate) is irradiated with the laser beam, or in the state in which the properties of sapphire are not yet changed. The transmittance of 80% or higher is preferable and 90% or higher is more preferable.

Though laser beam irradiation for forming break lines (processed portions 220) may be done from the side on which the nitride semiconductor is formed (the side on which multi-layered structure 150 is formed), considering absorption by the nitride semiconductor, irradiation from the back surface side of transparent substrate 110 (the side on which multi-layered structure 150 is not formed) is preferred.

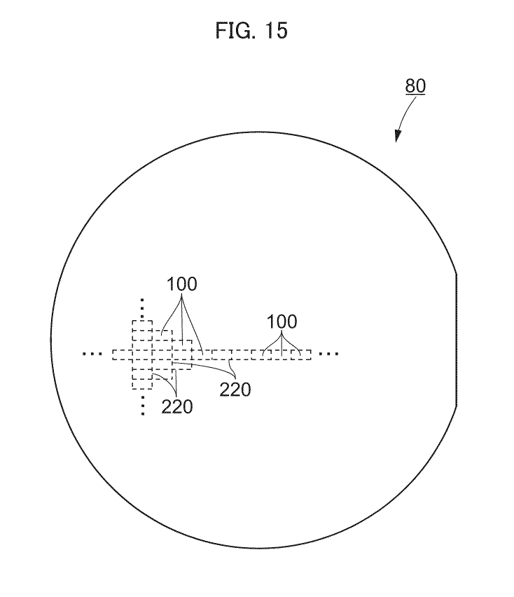

In the present embodiment, the break lines (processed portions 220) are formed by one-stage processing. Further, the break lines are formed linearly at a position apart by T3 (about 80 μm) in the thickness direction from the main surface 110a (the surface on which multi-layered structure 150 is formed) of transparent substrate 110. Thus, a wafer 80 shown in FIG. 15 is obtained.

Referring to FIG. 15, wafer 80 is a collection of elements, that is, a set of a plurality of semiconductor light emitting elements 100, and the above-described processed portions 220 (break lines) are formed between adjacent semiconductor light emitting elements 100.

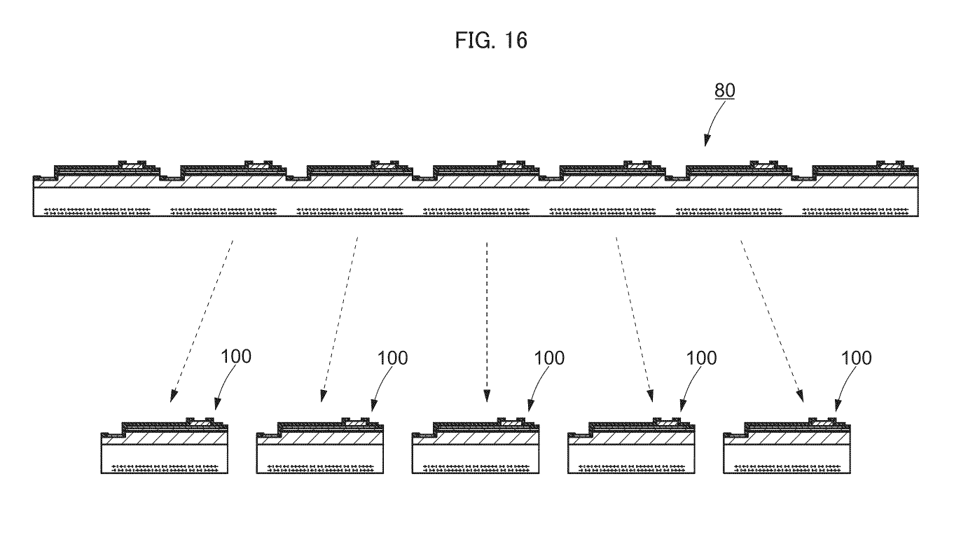

Finally, as shown in FIGS. 15 and 16, wafer 80 is divided into chips or individual semiconductor light emitting elements 100, using the formed break lines as starting points. Thus, semiconductor light emitting element 100 in accordance with the present embodiment is obtained.

As is apparent from the description above, semiconductor light emitting element 100 in accordance with the present embodiment attains the following effects.

In semiconductor light emitting element 100 using transparent substrate 110, light scattering structure 200 is formed inside the transparent substrate 110. On transparent substrate 110, multi-layered structure 150 including a semiconductor multi-layered film is formed, and the light emitted by multi-layered structure 150 enters transparent substrate 110. Light scattering structure 200 scatters the light from multi-layered structure 150 (MQW light emitting layer 130) that has entered transparent substrate 110, and makes it easier to take out the light from side surface 110b of transparent substrate 110. Thus, the efficiency of extracting light to the outside can be improved.

No matter whether semiconductor light emitting element 100 is sealed by a transparent resin having the refractive index of about 1.4 to about 1.5, it becomes possible by light scattering structure 200 to take out the light that entered transparent substrate 110 from side surface 110b of transparent substrate 110 with high efficiency. Further, since the above-described light scattering structure 200 is formed in transparent substrate 110, decrease of light scattering effect experienced when the light emitting element is mounted on a stem using a die bonding paste of transparent silicone resin, for example, having the refractive index of about 1.5, can be reduced. Therefore, by the configuration as described above, it is possible to improve the efficiency of extracting light to the outside even when semiconductor light emitting element 100 is in a mounted state.

The above-described light scattering structure 200 reflects light such that the incident angle of light to the side surface 110b of transparent substrate 110 becomes smaller. Thus, the efficiency of extracting light to the outside can further be improved.

The plurality of light scattering portions 210 forming light scattering structure 200 are dispersed in a plane in transparent substrate 110, and the scatterer layer E is formed by the plurality of light scattering portions 210 dispersed in a plane. Since the scatterer layer E formed of the plurality of light scattering portions 210 is provided in transparent substrate 110, the light entering transparent substrate 110 from multi-layered structure 150 can efficiently be scattered at the scatterer layer E. As a result, high light scattering effect can be attained and the efficiency of extracting light to the outside can be improved.

Since a plurality of scatterer layers E are arranged in multi-stages to be opposite to each other, the light entering transparent substrate 110 from multi-layered structure 150 can be scattered with higher efficiency by these scatterer layers E.

Further, light scattering portions 210 forming each scatterer layer E are arranged not to overlap with the light scattering portions of another scatterer layer E of a different stage when viewed two-dimensionally. If the positions of light scattering portions 210 of a scatterer layer E overlap with light scattering portions 210 of another scatterer layer E of a different stage, mechanical strength at the overlapping area of transparent substrate 110 decreases. Thus, transparent substrate 110 tends to crack. By arranging light scattering portions 210 forming each scatterer layer E not to overlap with the light scattering portions of another scatterer layer E of a different stage when viewed two-dimensionally, decrease in strength of transparent substrate 110 can be prevented. Further, by arranging light scattering portions 210 forming each scatterer layer E not to overlap with the light scattering portions of another scatterer layer E of a different stage when viewed two-dimensionally, the area where light scattering portions 210 exist can be made wider. This improves the light scattering effect, and the efficiency of extracting light to the outside can easily be improved.

By forming each of the plurality of light scattering portions in an approximately ellipsoidal shape extending in the thickness direction of transparent substrate 110, the light scattering effect can be improved.

Further, the plurality of light scattering portions 210 (light scattering structure 200) are formed in a region immediately below transparent electrode 170. A current is injected to the semiconductor multi-layered film through transparent electrode 170 and the region where the current is injected emits light. Therefore, by forming a plurality of light scattering portions at a region immediately below transparent electrode 170, it becomes possible to more effectively scatter the light emitted from multi-layered structure 150. As a result, the light can be extracted more easily from side surface 110b of transparent substrate 110.

Further, not much light enters the region immediately below p-side electrode 180 at an angle with which extraction of light from side surface 110b of transparent substrate 110 is difficult. Therefore, even when light scattering portions 210 are not formed in the region immediately below p-side electrode 180, the efficiency of extracting light to the outside can be improved.

Since light scattering portions 210 are implemented by heat denatured regions, light scattering portions 210 can be formed easily in transparent substrate 110, since the heat denatured region can be formed by laser irradiation. Further, if the heat denatured region becomes a cavity, the inside of cavity will be vacuum (refractive index: 1) and, therefore, the difference in refractive index from transparent substrate 110 increases. Thus, higher light scattering effect can be attained at light scattering portions 210.

At the side surface portion of transparent substrate 110, processed portions 220 (break lines), used as starting points for dividing transparent substrate 110, are formed, processed by laser beam irradiation. If the positions of these processed portions 220 coincide with the position of scatterer layer E in the thickness direction of transparent substrate 110, it is possible that the substrate is divided in an unintended direction when it is divided into chips, leading to lower production yield. By forming the processed portions 220 (break lines) at a position apart by a distance T3 from the upper surface of the substrate, different from the position of scatterer layer E in the thickness direction of transparent substrate 110, division in an unintended direction can be prevented. Thus, the production yield at the time of dicing to chips can be improved.

When light scattering portions 210 are formed by laser irradiation, if the pulsed laser output is high, a heat denatured region generates. If subjected to stress or the like, cracks may generate from the heat denatured region. If such a crack should reach MQW light emitting layer 130, optical output may decrease. Therefore, it is preferred that light scattering portions 210 formed of heat denatured regions are formed at positions apart by at least 10 μm in the thickness direction from the surface on which multi-layered structure 150 is formed (main surface 110a) of transparent substrate 110. By forming a plurality of light scattering portions 210 at such positions, decrease in optical output caused by cracks reaching MQW light emitting layer 130 can be prevented. In addition, the light scattering effect attained by light scattering portions 210 can easily be improved.

The method of manufacturing semiconductor light emitting element 100 in accordance with the present embodiment has the following effects.

After forming multi-layered structure 150 on main surface 110a of transparent substrate 110S, the back surface, on which multi-layered structure 150 is not formed, of transparent substrate 110S is removed, so that the substrate is reduced to a prescribed thickness. From the back surface side of transparent substrate 110 (110S) reduced to the prescribed thickness, a laser beam is directed to the inside of transparent substrate 110. By the laser irradiation, heat denatured regions are formed inside transparent substrate 110, and by the heat denatured regions, light scattering portions 210 are formed. Specifically, by directing the laser beam to the inside of transparent substrate 110, light scattering portions 210 are formed in transparent substrate 110. By dividing the substrate (wafer) having light scattering portions 210 thus formed, semiconductor light emitting elements 100 are provided. In transparent substrate 110 of the resulting semiconductor light emitting element 100, light scattering portions 210 are formed. As described above, light scattering portions 210 scatter light that has entered transparent substrate 110. On main surface 110a of transparent substrate 110, multi-layered structure 150 including a semiconductor multi-layered film is formed, and the light emitted by multi-layered structure 150 enters transparent substrate 110. Light scattering portions 210 scatter the light that entered transparent substrate 110 from multi-layered structure 150, and make it easier to extract the light from side surface 110b of transparent substrate 110. In this manner, a semiconductor light emitting element 100 with high efficiency of extracting light to the outside can easily be manufactured by the present manufacturing method.

Here, if the laser beam is directed to the inside of transparent substrate 110 from the side of main surface 110a on which multi-layered structure 150 is formed, it follows that the laser beam passes through multi-layered structure 150 including the semiconductor multi-layered film. This may have undesirable influence on characteristics of the element. Further, when an electrode is formed on multi-layered structure 150, the laser beam is blocked by the electrode and, hence, it becomes difficult to form light scattering portions 210 below the portion where the electrode is formed.

According to the method of manufacturing semiconductor light emitting element 100 of the present embodiment, the laser beam is directed to the inside of transparent substrate 110 from the back surface side on which multi-layered structure 150 is not formed, whereby light scattering portions 210 are formed. Thus, the laser beam does not pass through multi-layered structure 150 when light scattering portions 210 are formed. Thus, degradation of element characteristics caused by the laser beam passing through multi-layered structure 150 can be prevented. Even when an electrode is formed on multi-layered structure 150, light scattering portions 210 can easily be formed inside transparent substrate 110, since the laser beam is introduced from the side opposite to the side where the electrode is formed.

Further, since light scattering portions 210 are formed near the back surface of transparent substrate 110, light scattering portions 210 are formed at positions apart from multi-layered structure 150. The temperature near the focal point of laser beams becomes high. Therefore, by forming light scattering portions 210 away from the semiconductor multi-layered film, the influence of heat on the semiconductor multi-layered film can be reduced. Thus, thermal degradation and alteration of semiconductor multi-layered film resulting from the heat of laser irradiation can be prevented. At the time of forming light scattering portions 210, by forming light scattering portions 210 at a region closer to the back surface side than the intermediate position (dotted line G) between main surface 110a and the back surface in the thickness direction of transparent substrate 110, the influence of heat on the semiconductor multi-layered film can easily be reduced. Further, semiconductor light emitting element 100, which can directly utilize the light extracted from side surface 110b of transparent substrate 110, of the light emitted from multi-layered structure 150 to transparent substrate 110, can easily be manufactured.

Further, by forming light scattering portions 210 near the back surface of transparent substrate 110, the influence of heat on the semiconductor multi-layered film can further be reduced. In addition, in semiconductor light emitting element 100, of the light emitted from multi-layered structure 150 to transparent substrate 110, the light extracted form side surface 110b of transparent substrate 110 can easily be utilized directly.

As Example 1 of the semiconductor light emitting element, a semiconductor light emitting element having the same structure as semiconductor light emitting element 100 described in the embodiment above was fabricated. The light scattering structure in the transparent substrate consisted of two stages of scatterer layers. Each of the light scattering portions forming the scatterer layer had the height t=7 μm, width d=2 μm, pitch p1=6 μm and pitch p2=8 μm. The positions of respective scatterer layers (positions in the thickness direction of the substrate) were T1=100 μm and T2=90 μm, as in the embodiment described above.

A semiconductor light emitting element similar to Example 1 except that the light scattering structure is not formed in the transparent substrate was fabricated as Comparative Example 1 (reference element).

The light emitting elements of Example 1 and Comparative Example 1 were driven under the same driving conditions and optical outputs (total luminous flux) were measured. The optical output of Comparative Example 1 was 85.0 W, while the optical output of Example 1 was 87.6 mW. Thus, it was confirmed that the light emitting element of Example 1 has the optical output improved by about 3% from the light emitting element of Comparative Example 1.

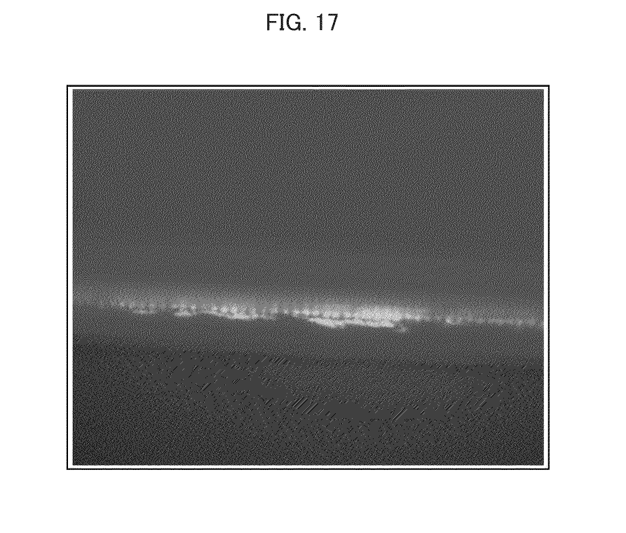

By directing blue light to the light emitting element of Example 1, scattering of light by the light scattering structures was observed. The results are as shown in FIG. 17. In FIG. 7, bright portions correspond to the light scattering structure. Thus, from FIG. 17, we can confirm that light is scattered by the light scattering structure.

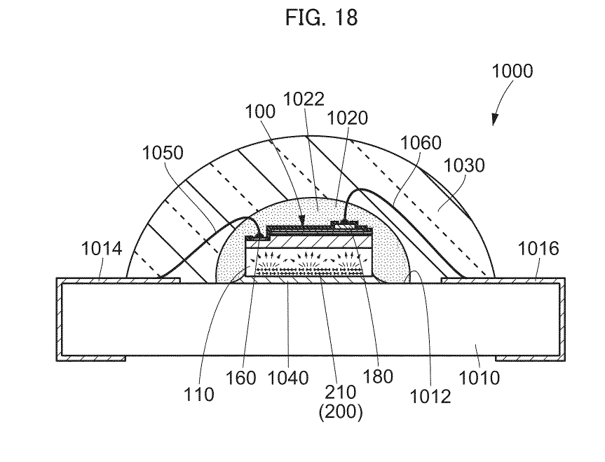

Referring to FIG. 18, a semiconductor light emitting device 1000 in accordance with the present embodiment includes, as a light source, semiconductor light emitting element 100 described in the first embodiment. Semiconductor light emitting device 1000 further includes a base 1010 on which semiconductor light emitting element 100 is mounted, a fluorescent layer 1020 sealing semiconductor light emitting element 100 mounted on base 1010, and a transparent resin layer 1030 covering fluorescent layer 1020.

Base 1010 is a mounting substrate having a main surface 1012 extending as a plane. Base 1010 functions as a mounting portion on which semiconductor light emitting element 100 is mounted. Base 1010 includes electrode terminals 1014 and 1016 electrically connected to semiconductor light emitting element 100. Semiconductor light emitting element 100 is coupled to main surface 1012 of base 1010 by means of a bonding layer 1040 of die bonding paste. The die bonding paste is formed of a transparent resin material such as silicone resin or epoxy resin. Metal material having low melting point such as solder may be used as the die bonding paste.

Semiconductor light emitting element 100 mounted on base 1010 is electrically connected to electrode terminals 1014 and 1016 of base 1010 through wires 1050 and 1060 formed, for example, of gold. Specifically, an n-side electrode 160 of semiconductor light emitting element 100 is electrically connected to electrode terminal 1014 through wire 1050, and a p-side electrode 180 of semiconductor light emitting element 100 is electrically connected to electrode terminal 1016 through wire 1060.

Fluorescent layer 1020 is formed of a light transmitting resin that passes light emitted from semiconductor light emitting element 100. Fluorescent layer 1020 is formed, for example, of transparent epoxy resin or silicone resin. Fluorescent layer 1020 contains fluorescent substance that changes the wavelength of light emitted from semiconductor light emitting element 100, and functions as a wavelength converting portion. Specifically, a plurality of fluorescent particles 1022 are dispersed in fluorescent layer 1020. The light emitted from semiconductor light emitting element 100 has its wavelength converted by fluorescent particles 1022 and, therefore, light having the wavelength different from that of light emitted from semiconductor light emitting element 100 is emitted from fluorescent layer 1020. By way of example, BOSE (Ba, O, Sr, Si, Eu) or the like may suitably be used as fluorescent particles 1022. Other than BOSE, SOSE (Sr, Ba, Si, O, Eu), YAG (Ce-activated Yttrium-Aluminum-Garnet), α sialon ((Ca), Si, Al, O, N, Eu), β sialon (Si, Al, O, N, Eu) or the like may suitably be used. The type of fluorescent particles 1022 may be appropriately adjusted in view of the wavelength of excited light and the color of light emission.

Transparent resin layer 1030 is formed of resin that passes light emitted from semiconductor light emitting element 100 and fluorescent layer 1020. Transparent resin layer 1030 is formed, for example, of a transparent epoxy resin or silicone resin. Transparent resin layer 1030 is provided outside of fluorescent layer 1020, and it seals wires 1050 and 1060. Thus, it protects semiconductor light emitting element 100 as well as wires 1050 and 1060.

In the present embodiment, fluorescent layer 1020 is provided on main surface 1012 to surround semiconductor light emitting element 100 and, transparent resin layer 1030 is provided to further cover fluorescent layer 1020. Fluorescent layer 1020 is formed to fill the space between semiconductor light emitting element 100 and transparent resin layer 1030 on the main surface 1012. Fluorescent layer 1020 and transparent resin layer 1030 are both formed in the shape of a dome.

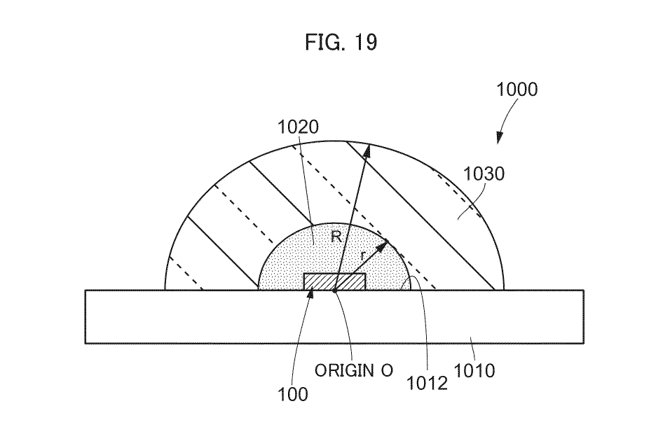

Referring to FIG. 19, fluorescent layer 1020 and transparent resin layer 1030 have radii r and R, respectively, and formed as concentric semi-spheres with the origin O as the center. Origin O is positioned on main surface 1012. Semiconductor light emitting element 100 is arranged at a position superposed on origin O.

Assuming that transparent resin layer 1030 has a refractive index of n1, it is preferred that fluorescent layer 1020 has a refractive index n2 larger than n1. Then, it follows that fluorescent layer 1020 having higher refractive index is arranged around semiconductor light emitting element 100 and, thus, the light extracting efficiency from semiconductor light emitting element 100 can further be improved.

Further, it is more preferable that fluorescent layer 1020 and transparent resin layer 1030 are formed to satisfy Equation (1) below:

R>r·n1 (1)

where R represent the radius of transparent resin layer 1030, r represents the radius of fluorescent layer 1020 and n1 represents the refractive index of transparent resin layer 1030.

By such a configuration, the light emitted from semiconductor light emitting element 100 and from fluorescent layer 1020 can be prevented from being reflected by the outer surface of transparent resin layer 1030 (interface between transparent resin layer 1030 and the atmospheric air). Thus, it becomes possible to extract the light emitted from semiconductor light emitting element 100 and fluorescent layer 1020 to the outside with high efficiency. In addition, orientation of light emitted from semiconductor light emitting element 100 and fluorescent layer 1020 can easily be controlled. In the present embodiment, the direction of emitted light is controlled to proceed in the upward direction (the direction opposite to the base 1010).

As is apparent from the foregoing, semiconductor light emitting device 1000 in accordance with the present embodiment attains the following effects.

Semiconductor light emitting device 1000 has the semiconductor light emitting element 100 described in the first embodiment mounted thereon. Semiconductor light emitting element 100 has light scattering portions 210 formed inside transparent substrate 110. Light scattering portions 210 scatter the light entering transparent substrate 110 from multi-layered structure 150 and improve the light extracting efficiency of semiconductor light emitting element. Since semiconductor light emitting element 100 as such is mounted, semiconductor light emitting device 1000 having high efficiency of extracting light to the outside can be obtained.

Further, in semiconductor light emitting device 1000 of the present embodiment, since light scattering portions 210 are formed in transparent substrate 110 of semiconductor light emitting element 100, it is possible to improve the efficiency of extracting light to the outside without using a material having high reflection/scattering characteristics for base 1010 on which semiconductor light emitting element 100 is mounted. This increases the degree of freedom in designing the semiconductor light emitting device.

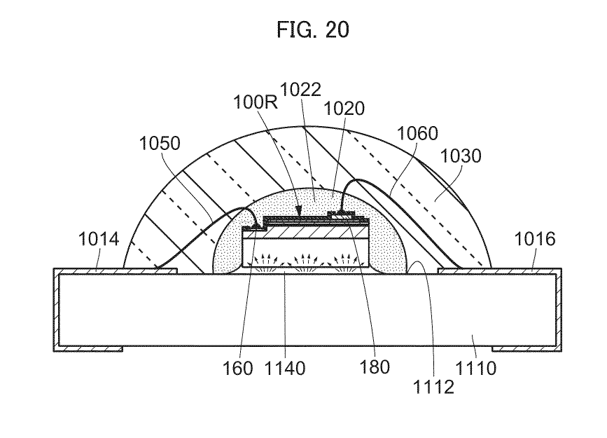

This point will be described in greater detail with reference to FIG. 20. A semiconductor light emitting element 110R not having the light scattering portions cannot attain the reflection/scattering effects of the light scattering portions. Thus, in order to scatter/reflect the light entering the transparent substrate from the multi-layered structure, it is necessary to improve the reflection/scattering characteristics of a main surface 1112 of base 1110 on which semiconductor light emitting element 100 is mounted. In that case, it is necessary to use a material having high reflection/scattering characteristics at least as the material of a portion below semiconductor light emitting element 110R, of base 1110. Therefore, in a semiconductor light emitting device mounting semiconductor light emitting element 100 not having the light scattering portions formed therein, it is difficult to improve the degree of freedom in design. Further, use of a material having high reflection/scattering characteristics for base 1010 leads to increased manufacturing cost.

Semiconductor light emitting device 1000 in accordance with the present embodiment can improve the degree of freedom in design as described above. Therefore, it is possible, for example, not to use a material having high reflection/scattering characteristics for the mounting portion. Such a configuration reduces cost.

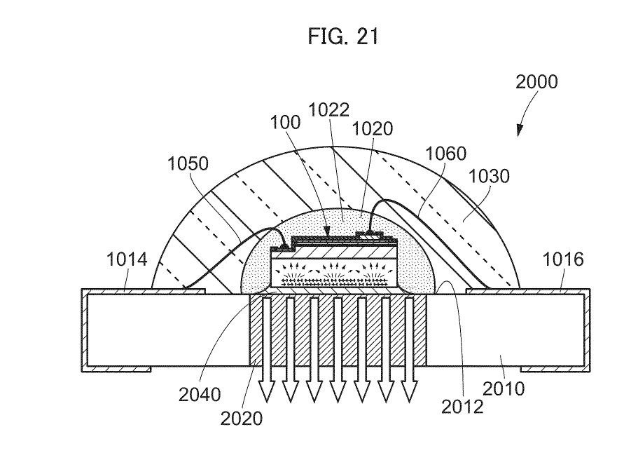

Referring to FIG. 21, a semiconductor light emitting device 2000 in accordance with the present embodiment has substantially the same configuration as semiconductor light emitting device 1000 of the second embodiment. It is different from the second embodiment, however, in that the present embodiment uses a base 2010 including a heat radiator with high heat radiating characteristic (hereinafter referred to as “high heat radiator”) 2020 is used.

Part of base 2010 is formed of high heat radiator 2020. High heat radiator 2020 is provided at the mounting portion where semiconductor light emitting element 100 is mounted. High heat radiator 2020 is formed, for example, of Al or Al alloy. High heat radiator 2020 is preferably formed of a material containing at least one selected from the group consisting of: Al, Ag, Au, Cu, Mo, W, Sn, C, SiC, AlN and Si.

Further, in the present embodiment, a metal material having low melting point such as solder is used as the die bonding paste. Therefore, semiconductor light emitting element 100 is coupled to main surface 2012 (on high heat radiator 2020) of base 2010 by means of a coupling layer 2040 formed of metal material with low melting point. The heat generated when semiconductor light emitting element 100 is driven is transmitted through coupling layer 2040 of metal material having low melting point to high heat radiator 2020, and radiated from high heat radiator 2020. In FIG. 21, white arrows schematically show the movement of heat.

As is apparent from the foregoing, semiconductor light emitting device 2000 in accordance with the present embodiment attains the following effects.

Since the portion where semiconductor light emitting element 100 is mounted of base 2010 is formed of high heat radiator 2020, the heat radiating characteristic of semiconductor light emitting device 2000 can be improved. Since the heat radiating characteristic is improved, decrease of luminance caused by the heat generated by semiconductor light emitting element 100 when it is driven can be prevented.

By forming high heat radiator 2020 from a material containing at least one selected from the group consisting of Al, Ag, Au, Cu, Mo, W, Sn, C, SiC, MN and Si, the heat radiating characteristic can be improved. By forming the mounting portion using high heat radiator 2020 as such, the heat radiating characteristic of semiconductor light emitting device 2000 can further be improved.

Further, since semiconductor light emitting element 100 is coupled to high heat radiator 2020 by means of coupling layer 2040 formed of metal material having low melting point, the heat generated by semiconductor light emitting element 100 can effectively be transmitted to high heat radiator 2020. Therefore, the heat generated at semiconductor light emitting element 100 can effectively be radiated from high heat radiator 2020 and, thus, the heat radiating characteristic of semiconductor light emitting device 2000 can further be improved. Further, since light scattering portions 210 (see FIG. 1) are formed in transparent substrate 110 (see FIG. 1) of semiconductor light emitting element 100, the efficiency of extracting light to the outside can be improved even when the coupling layer formed of metal material having low melting point is used as coupling layer 2040 for coupling semiconductor light emitting element 100 to high heat radiator 2020.

As shown in FIG. 20, in a semiconductor light emitting device mounting semiconductor light emitting element 110R not having the light scattering portions formed therein, if base 1110 is formed of a material having high heat conductivity such as metal in order to improve the heat radiating characteristic, it is necessary to use a material having high reflectance with respect to the wavelength of light emitted from semiconductor light emitting element 110R and to mirror-finish the main surface. Particularly if the wavelength of light emitted from semiconductor light emitting element is in the range of blue to ultraviolet, usable metal material is limited. By way of example, Ag or the like is difficult to handle, since it is prone to blackening and migration with the light having the wavelength of this range. Further, in the semiconductor light emitting device shown in FIG. 20, a light transmitting material must be used as the die bonding paste (coupling layer 1140) (generally, resin material such as silicone resin and epoxy resin). Since such a resin material has low heat conductivity, heat hardly transmits from semiconductor light emitting element 110R to base 1110.

Again referring to FIG. 21, semiconductor light emitting device 2000 in accordance with the present embodiment can improve the efficiency of extracting light to the outside by the light emitting element itself, since light scattering portions 210 are formed in transparent substrate 110 of semiconductor light emitting element 100 mounted therein. Therefore, it is unnecessary to use a material having high reflectance to the wavelength of light emitted from semiconductor light emitting element 100 for base 2010 (high heat radiator 2020). Mirror finish of the main surface is not necessary, either. Further, a process such as Ag plating is unnecessary and, therefore, measures for preventing blackening and migration are also unnecessary. In addition, since semiconductor light emitting element 100 is mounted using coupling layer 2040 formed of metal material having low melting point, heat radiation characteristic can effectively be improved.

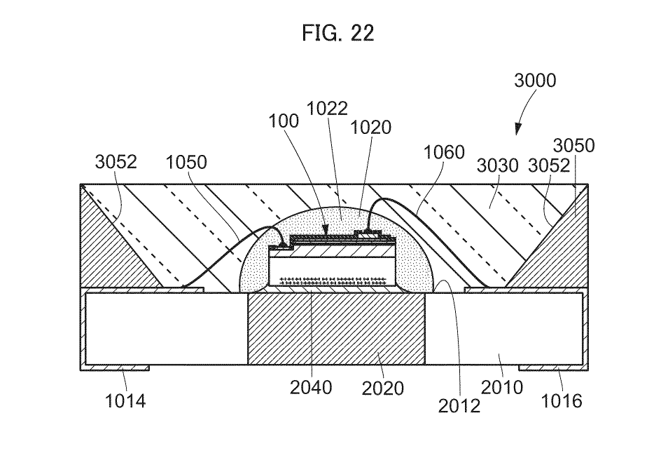

Referring to FIG. 22, a semiconductor light emitting device 3000 in accordance with the present embodiment corresponds to semiconductor light emitting device 2000 of the third embodiment, and it additionally includes a reflecting member 3050. Reflecting member 3050 reflects light emitted from semiconductor light emitting element 100 and fluorescent layer 1020 and controls light orientation. Reflecting member 3050 is mounted on a main surface 2012 of base 2010 to surround semiconductor light emitting element 100. Reflecting member 3050 has a reflecting surface 3052 that reflects light. As reflecting member 3050 is mounted on main surface 2012 of base 2010, reflecting surface 3052 comes to be provided outside of fluorescent layer 1020. Reflecting surface 3052 is formed to be an inclined surface, for adjusting the direction of emitted light to the upward direction (the direction opposite to base 2010).

In the present embodiment, in place of transparent resin layer 1030 (see FIG. 21) of semiconductor light emitting device 2000, a transparent resin layer 3030 is filled in a region inside the reflecting member 3050. Transparent resin layer 3030 is formed, similar to transparent resin layer 1030, of a resin that passes light emitted from semiconductor light emitting element 100 and fluorescent layer 1020 (for example, transparent epoxy resin or silicone resin).

Semiconductor light emitting device 3000 in accordance with the present embodiment attains the same effect as attained by semiconductor light emitting device 2000 in accordance with the third embodiment above.

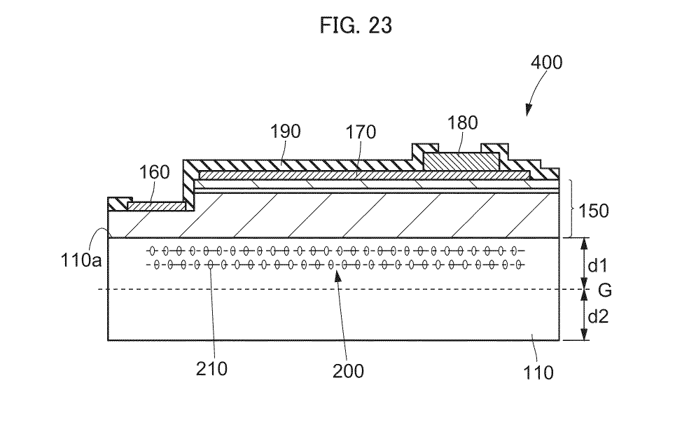

Referring to FIG. 23, a semiconductor light emitting element 400 in accordance with the present embodiment has substantially the same configuration as semiconductor light emitting element 100 of the first embodiment. It is noted, however, that semiconductor light emitting element 400 of the present embodiment is different in that light scattering portions 210 are formed in a region on the side of multi-layered structure 150, from the first embodiment in which they are formed in a region opposite to multi-layered structure 150.

A plurality of light scattering portions 210 are formed in a region closer to main surface 110a than the intermediate position (dotted line G) between the main surface 110a of transparent substrate 110 and the back surface opposite to main surface 110a. Here, the plurality of light scattering portions 210 may be formed in the vicinity of main surface 110a of transparent substrate 110.

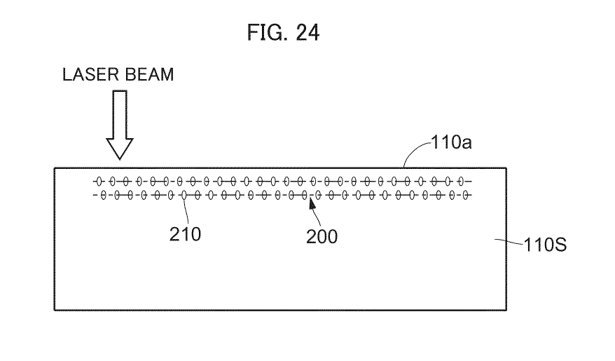

Referring to FIGS. 24 to 27, the method of manufacturing semiconductor light emitting element 400 in accordance with the present embodiment will be described.

According to the method of manufacturing semiconductor light emitting element 400 of the present embodiment, before forming multi-layered structure 150, a plurality of light scattering portions 210 are formed in transparent substrate 110.

Specifically, first, a transparent substrate 110S of sapphire, having the thickness of about 400 μm to about 1300 μm is prepared. By mirror-polishing main surface 110a (on which nitride semiconductor layer is to be formed) of transparent substrate 110S, that surface comes to be the mirror-state (with the surface roughness Ra of 1 nm or smaller).

Next, as shown in FIG. 24, transparent substrate 110S is irradiated with laser beams, so that the plurality of light scattering portions 210 are formed inside transparent substrate 110S. The method of forming light scattering portions 210 is the same as that described with reference to the first embodiment.

In the present embodiment, the laser beam is directed to the inside of transparent substrate 110S from the side of the surface (main surface 110a) on which multi-layered structure 150 is to be formed at subsequent process steps, whereby the plurality of light scattering portions 210 are formed near the main surface 110a.

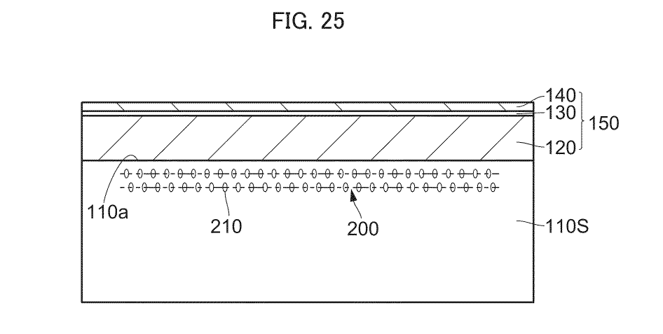

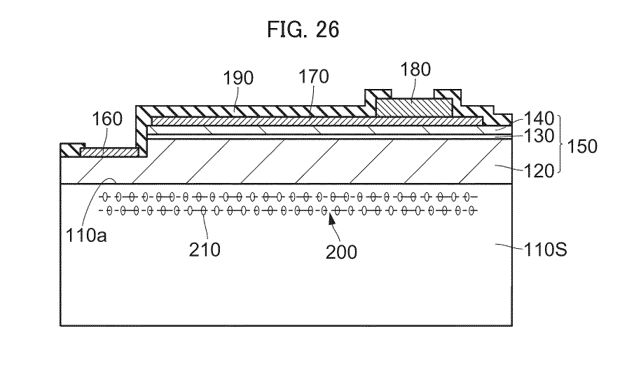

Referring to FIG. 25, using transparent substrate 110S having light scattering portions 210 formed therein, by the same method as in the first embodiment, on main surface 110a of transparent substrate 110S, the same multi-layered structure 150 is formed. Thereafter, as shown in FIG. 26, by the same method as in the first embodiment, part of multi-layered structure 150 is removed by etching, and n-side electrode 160, transparent electrode 170 and p-side electrode 180, as well as transparent protective film 190 are formed. Then, the substrate with the electrodes formed is subjected to heat processing, whereby the electrodes are alloyed.

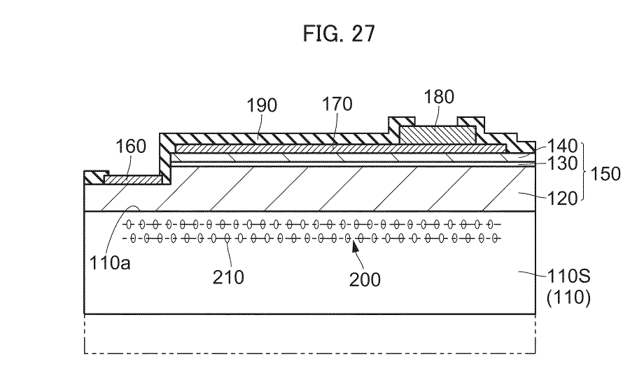

Next, as show in FIG. 27, the wafer fabricated in the above-described manner is ground and polished, to reduce the thickness of transparent substrate 110S. Finally, the fabricated wafer is divided into chips of individual semiconductor light emitting elements 400. Thus, semiconductor light emitting element 400 in accordance with the present embodiment is obtained. The process step of reducing the thickness of wafer (substrate) through grinding and polishing and the process step of dividing the wafer to chips are the same as those of the first embodiment described above. Therefore, description thereof will not be repeated.

As is apparent from the description above, semiconductor light emitting element 400 in accordance with the present embodiment attains the following effects.

By directing the laser beams from the side of one surface of transparent substrate 110S, light scattering portions 210 are formed in transparent substrate 110S. Using transparent substrate 110S having light scattering portions 210 formed therein, multi-layered structure 150 including a semiconductor multi-layered film is formed on transparent substrate 110S. After forming multi-layered structure 150, the back surface, on which multi-layered structure 150 is not formed, of transparent substrate 110S is removed until the substrate thickness is reduced to a prescribed thickness. By dividing the transparent substrate (wafer), semiconductor light emitting element 400 is obtained.

In the present embodiment, light scattering portions 210 are formed inside transparent substrate 110S (110) before forming multi-layered structure 150. Therefore, the semiconductor multi-layered film (multi-layered structure 150) is free from the influence of heat cause by laser irradiation. Therefore, the positions for forming light scattering portions 210 can be determined freely, in accordance with the intended use of semiconductor light emitting element 400.

Further, since light scattering portions 210 are formed close to the surface (main surface 110a) of transparent substrate 110S on which multi-layered structure 150 is to be formed and thereafter the multi-layered structure 150 is formed, it is possible to form light scattering portions 210 in the region close to multi-layered structure 150. According to the present manufacturing method, light scattering portions 210 are formed first and thereafter the multi-layered structure 150 is formed and, therefore, even though light scattering portions 210 are formed in the vicinity of multi-layered structure 150, the semiconductor multi-layered film (multi-layered structure 150) is free from the influence of heat caused by laser irradiation. Therefore, it is possible to form light scattering portions 210 close to multi-layered structure 150 while preventing degradation of element characteristics caused by heat. In addition, since light scattering portions 210 are formed close to multi-layered structure 150, a semiconductor light emitting element having high axial light intensity (with laterally proceeding light reduced) can easily be manufactured.

Further, since the laser beam is directed from the side of main surface 110a of transparent substrate 110, on which multi-layered structure 150 is to be formed, light scattering portions 210 can easily be formed in the vicinity of multi-layered structure 150.

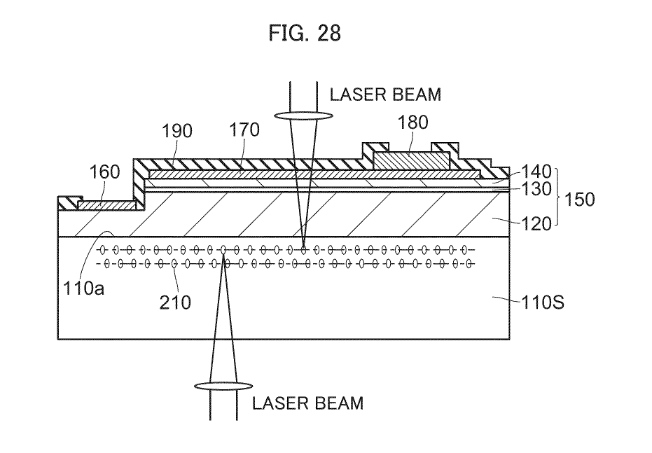

Referring to FIG. 28, as described in the first embodiment, if multi-layered structure 150 is formed and thereafter the laser beam is directed to the inside of transparent substrate 110 from the side of main surface 110a on which multi-layered structure 150 has been formed, it follows that the laser beam passes through multi-layered structure 150 and, therefore, element characteristics may possibly be affected. Further, if an electrode is formed on the multi-layered structure 150, the laser beam would be blocked by the electrode and it becomes difficult to form the light scattering portions below the portion where the electrode is formed. Even when the laser beam is directed to the inside of transparent substrate 110 from the back surface of transparent substrate 110, the heat generated by laser beam irradiation affects the semiconductor multi-layered film (multi-layered structure 150) if the laser irradiation is done after the formation of multi-layered structure 150. Therefore, various characteristics of the element may be affected by the heat caused by laser irradiation.

As described above, by the method of manufacturing semiconductor light emitting element 400 in accordance with the present embodiment, such disadvantages can be avoided, and light scattering portions 210 can be formed in the vicinity of multi-layered structure 150.

The semiconductor light emitting device in accordance with the present embodiment has the same configuration as semiconductor light emitting element 100 in accordance with the first embodiment. It is noted, however, that the semiconductor light emitting element of the present embodiment is manufactured through a method different from the first embodiment.

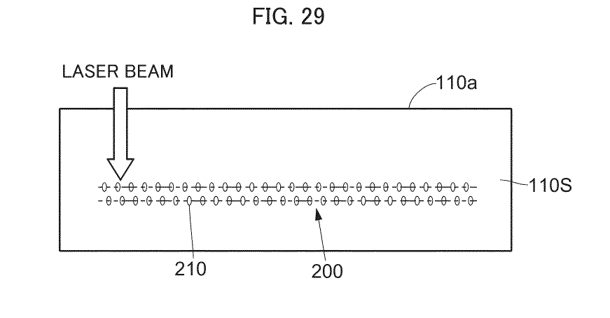

Referring to FIGS. 29 to 32, the method of manufacturing the semiconductor light emitting element in accordance with the present embodiment will be described.

As in the fifth embodiment, according to the method of manufacturing the semiconductor light emitting element of the present embodiment, a plurality of light scattering portions 210 are formed in transparent substrate 110 before forming multi-layered structure 150.

Specifically, first, a transparent substrate 110S of sapphire, having the thickness of about 400 μm to about 1300 μm is prepared. By mirror-polishing main surface 110a (on which nitride semiconductor layer is to be formed) of transparent substrate 110S, that surface comes to be the mirror-state (with the surface roughness Ra of 1 nm or smaller).

Thereafter, as shown in FIG. 29, transparent substrate 110S is irradiated with laser beams, so that the plurality of light scattering portions 210 are formed inside transparent substrate 110S. The method of forming light scattering portions 210 is the same as that described with reference to the first embodiment.

Laser irradiation is from the side of the surface (main surface 110a) on which multi-layered structure 150 is to be formed at subsequent process steps. In the present embodiment, different from the fifth embodiment, the focal position of laser beams is adjusted such that the plurality of light scattering portions are positioned in a region closer to the back surface than the intermediate position of the transparent substrate. The positions for forming light scattering portions 210 are determined considering the thickness of transparent substrate 110S and how much the back surface is to be removed in the subsequent process steps of grinding and polishing. Here, it is preferred that the plurality of light scattering portions 210 are formed to be positioned close to the back surface of transparent substrate 110 after the manufacturing of semiconductor light emitting element is finished.

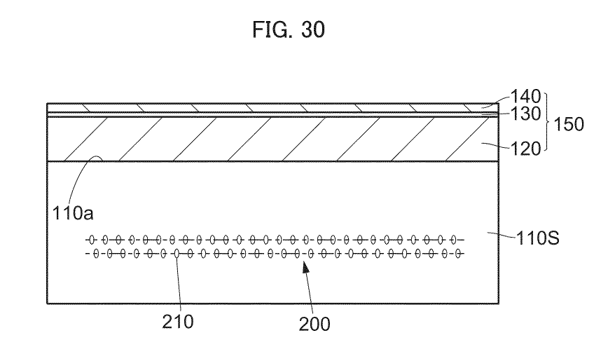

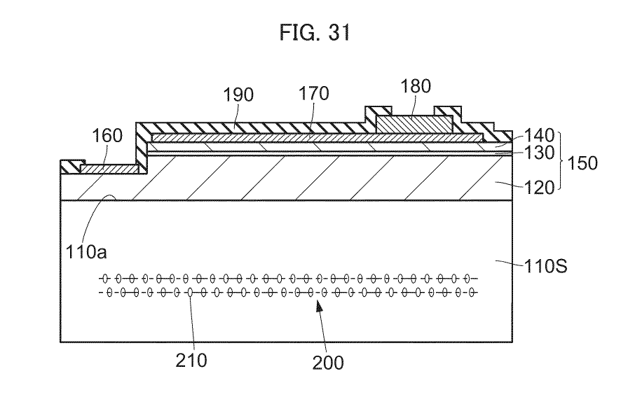

Referring to FIG. 30, using transparent substrate 110S having light scattering portions 210 formed therein, by the same method as in the first embodiment, on main surface 110a of transparent substrate 110S, the same multi-layered structure 150 is formed. Thereafter, as shown in FIG. 31, by the same method as in the first embodiment, part of multi-layered structure 150 is removed by etching, and n-side electrode 160, transparent electrode 170 and p-side electrode 180, as well as transparent protective film 190 are formed. Then, the substrate with the electrodes formed is subjected to heat processing, whereby the electrodes are alloyed.

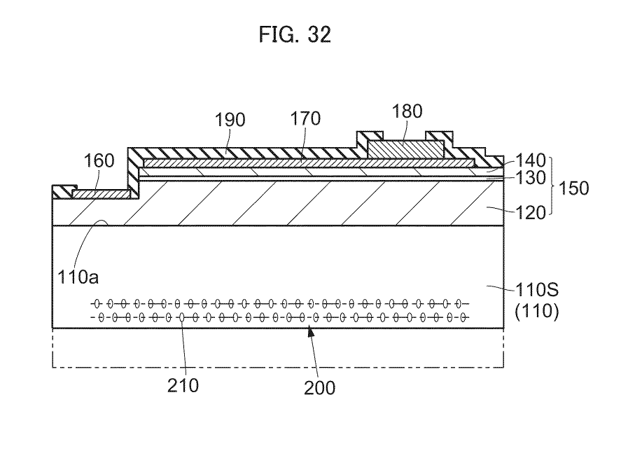

Next, as show in FIG. 32, the wafer fabricated in the above-described manner is ground and polished, to reduce the thickness of transparent substrate 110S. Here, the back surface of the wafer (substrate) is removed such that the plurality of light scattering portions 210 come to be positioned near the back surface of transparent substrate 110. Finally, the fabricated wafer is divided into chips of individual semiconductor light emitting elements. Thus, the semiconductor light emitting element of the present embodiment is obtained.

As is apparent from the description above, the method of manufacturing a semiconductor light emitting element in accordance with the present embodiment attains the following effects.

Before forming multi-layered structure 150, a plurality of light scattering portions 210 are formed in transparent substrate 110S (110). Here, light scattering portions 210 are formed at a region on the side closer to the back surface than the intermediate position between main surface 110a and the back surface in the thickness direction of transparent substrate 110. Thus, a semiconductor light emitting element, which can directly utilize the light extracted from side surface 110b (see FIG. 1) of transparent substrate 110, of the light emitted from multi-layered structure 150 to transparent substrate 110, can easily be manufactured, while effectively reducing the influence of heat on the semiconductor multi-layered film.

Further, as the back surface of the wafer (substrate) is removed such that light scattering portions 210 come to be positioned near the back surface of transparent substrate 110, the light scattering portions 210 can easily be formed in the vicinity of back surface of transparent substrate 110. Since light scattering portions 210 are formed close to the back surface of transparent substrate 110, it becomes possible to directly utilize, of the light emitted from multi-layered structure 150 to transparent substrate 110, the light extracted from side surface 110b of transparent substrate 110.

The semiconductor light emitting element in accordance with the present embodiment differs from the one in accordance with the first embodiment in that a transparent substrate formed of nitride semiconductor is used. As the transparent substrate of nitride semiconductor, a c-plane GaN substrate is used. Except for this point, the configuration is the same as that of the first embodiment.

As Example 2, the same semiconductor light emitting device as the semiconductor light emitting device in accordance with the present embodiment above was fabricated. A semiconductor light emitting element similar to Example 2 except that the light scattering structure is not formed in the transparent substrate was fabricated as Comparative Example 2 (reference element).

The light emitting elements of Example 2 and Comparative Example 2 were driven under the same driving conditions and optical outputs (total luminous flux) were measured. The results indicated that the optical output of light emitting element of Example 2 was improved by about 5% than the light emitting element of Comparative Example 2.

In the semiconductor light emitting element using a GaN substrate as the transparent substrate, the substrate has refractive index of 2.5, which is larger than 1.78 of the sapphire substrate. Therefore, the light extracting efficiency from the substrate side surface decreases as compared with a semiconductor light emitting element using a sapphire substrate. In Example 2 having the light scattering portions formed in the transparent substrate, higher optical output is considered to be the result of more effective improvement in light extracting efficiency than in the element using the sapphire substrate.

When a SiC substrate was used as the transparent substrate, similar results as when the GaN substrate was used as the transparent substrate were obtained. The reason for this may be that the effect of improvement was more effective as the SiC substrate has large refractive index as in the case of GaN substrate. Thus, it was confirmed that the embodiment was also effective for the SiC substrate.

The semiconductor light emitting element in accordance with the present embodiment is an ultraviolet LED having the emission wavelength of 290 nm. In the semiconductor light emitting element, the transparent substrate is a sapphire substrate, as transparent substrate 110 of the first embodiment. In the transparent substrate, the light scattering structures similar to those of the first embodiment are formed. On the transparent substrate, a semiconductor multi-layered film of nitride semiconductor is formed.

In the present embodiment, the composition and thickness of MQW light emitting layer are adjusted to emit the ultraviolet light having the emission wavelength of 290 nm. Specifically, the MQW light emitting layer is a light emitting layer of InAlGaN quaternary mixed crystal having In added to AlGaN. A few % of In is added to AlGaN of which Al composition ratio is about 70% to about 90%. The wavelength also differs depending on the thickness of light emitting layer (barrier layer, well layer). Therefore, the composition and thickness are appropriately adjusted to adjust the wavelength.

As Example 3, the same light emitting device as the semiconductor light emitting device in accordance with the present embodiment was fabricated. A semiconductor light emitting element similar to Example 3 except that the light scattering structure is not formed in the transparent substrate was fabricated as Comparative Example 3 (reference element).

The light emitting elements of Example 3 and Comparative Example 3 were driven under the same driving conditions and optical outputs (total luminous flux) were measured. The results indicated that the optical output of light emitting element of Example 3 was improved by about 3% than the light emitting element of Comparative Example 3.

Therefore, it was confirmed that the structure of the present embodiment having light scattering structures formed in the substrate was also effective in an ultraviolet LED.

The semiconductor light emitting element in accordance with the present embodiment is substantially the same light emitting element as semiconductor light emitting element 100 in accordance with the first embodiment described above. It is noted, however, that the present embodiment is different in that the scatterer layer is formed in one stage, from the first embodiment having two stages of the scatterer layers.

As Example 4, the same light emitting device as the semiconductor light emitting device in accordance with the present embodiment was fabricated. Each of the light scattering portions forming the scatterer layer had the height t=7 μm, width d=2 μm, pitch p1=6 μm and pitch p2=8 μm. The scatterer layer (light scattering portions) was formed at a position apart by 20 μm in the thickness direction from the main surface (upper surface) of transparent substrate. A semiconductor light emitting element similar to Example 4 except that the light scattering structure is not formed in the transparent substrate was fabricated as Comparative Example 4 (reference element).

The light emitting elements of Example 4 and Comparative Example 4 were driven under the same driving conditions and optical outputs (total luminous flux) were measured. The results indicated that the optical output of light emitting element of Example 4 was improved by about 2% than the light emitting element of Comparative Example 4.

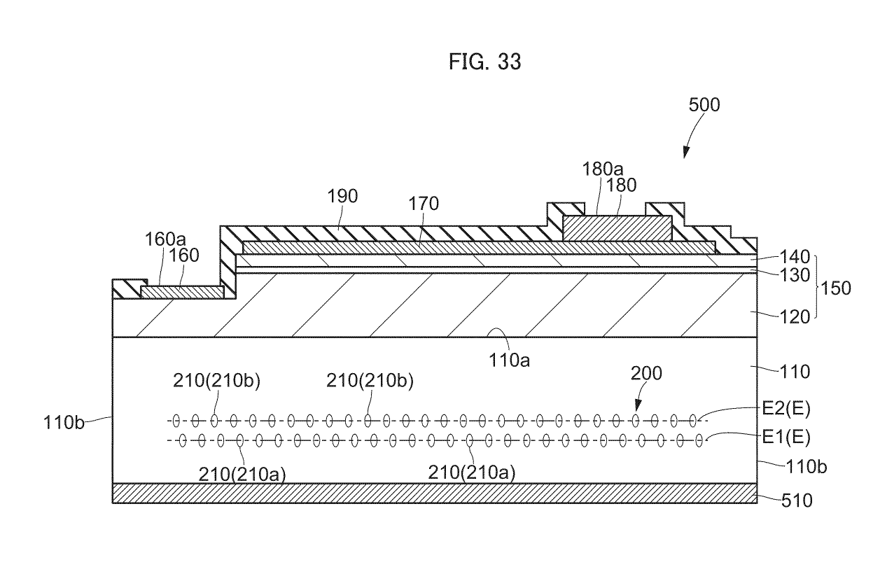

Referring to FIG. 33, a semiconductor light emitting element 500 in accordance with the present embodiment is substantially the same light emitting element as semiconductor light emitting element 100 in accordance with the first embodiment described above. It is noted, however, that the present embodiment is different from the first embodiment in that a reflection film 510 is formed on the back surface of transparent substrate 110.

Reflection film 510 is formed, for example, of a metal reflection film of Al or Ag. Another example may be a dielectric multi-layered reflection film of SiO₂/TiO₂ (of about 20 layers with the layer thickness being λ/4). Here, λ represents the peak wavelength of emission spectrum of the light emitting element. Further, it is possible to use a hybrid type reflection film structure prepared by forming, after forming such a multi-layered reflection film, a metal reflection film of Al or Ag on the multi-layered reflection film. Generally, any material that is optically transparent may be used as the material for the dielectric multi-layered reflection film. By way of example, Al₂O₃, ZrO₂, TaO₅, Nb₂O₅ or the like may be used without any problem as the material for the dielectric reflection film. Reflectance of reflection film 510 is preferably 80% or higher and, more preferably, 90% or higher.

By forming reflection film 510 on the back surface of transparent substrate 110, it becomes possible to effectively reflect the light entering from the upper surface of transparent substrate 110 by the back surface of transparent substrate. Thus, the light that reached the back surface of transparent substrate 110 can effectively be scattered by light scattering structure 200. Thus, the light can be extracted with higher efficiency from side surface 110b of transparent substrate 110.

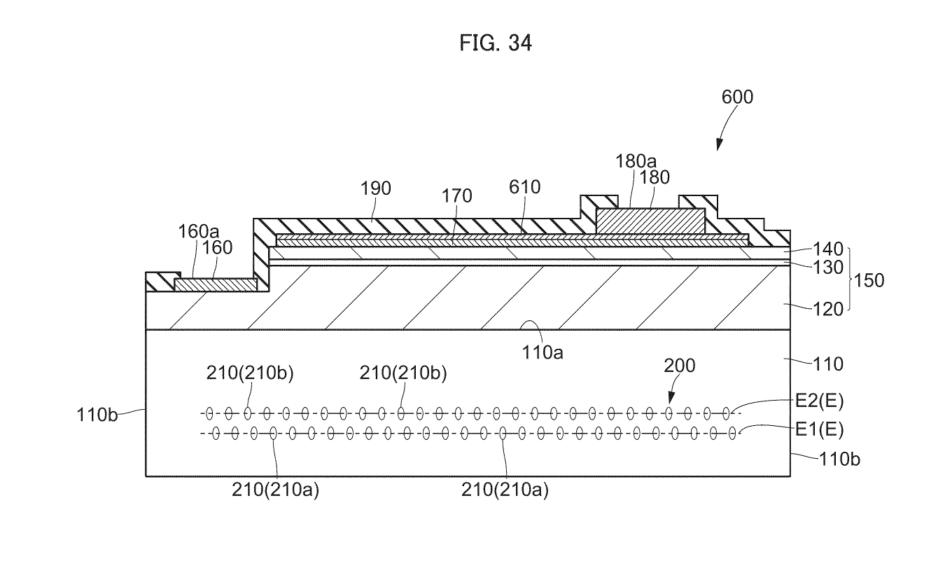

Referring to FIG. 34, a semiconductor light emitting element 600 in accordance with the present embodiment is a so-called flip-mount type LED light emitting element, which is mounted with the side having p-side electrode 180 facing downward. Semiconductor light emitting element 600 has the same configuration as semiconductor light emitting element 100 in accordance with the first embodiment. It is noted, however, that the present embodiment is different in that a reflection film 610 is formed on the upper surface of transparent electrode 170, from the first embodiment not having such a reflection film.

As Example 5, the same light emitting device as the semiconductor light emitting device in accordance with the present embodiment was fabricated. In Example 5, an Ag reflection film was formed on the transparent electrode. A semiconductor light emitting element similar to Example 5 except that the light scattering structure is not formed in the transparent substrate was fabricated as Comparative Example 5 (reference element).

The light emitting elements of Example 5 and Comparative Example 5 were each mounted in the flip-chip manner. Then, the light emitting elements of Example 5 and Comparative Example 5 were driven under the same driving conditions and optical outputs (total luminous flux) were measured. The results indicated that the optical output of light emitting element of Example 5 was improved by about 6% than the light emitting element of Comparative Example 5.

When flip-chip mounted, the present structure having the light scattering structures formed in the substrate allows effective extraction of light from the side surface of the substrate as well as the light totally reflected at the back surface of the substrate. Thus, it was confirmed that the present structure was effective in improving the light extraction efficiency. In order to further improve the light extraction efficiency, irregularities may be formed on the back surface of sapphire substrate.

The semiconductor light emitting element in accordance with the present embodiment uses a substrate of nitride semiconductor, as in the seventh embodiment described above. It is noted, however, that the present embodiment is different in that an m-plane GaN substrate, which is a non-polar substrate, is used as the transparent substrate, from the seventh embodiment in which a c-plane GaN substrate is used as the transparent substrate.

As Example 6, the same light emitting device as the semiconductor light emitting device in accordance with the present embodiment was fabricated. A semiconductor light emitting element similar to Example 6 except that the light scattering structure is not formed in the transparent substrate was fabricated as Comparative Example 6 (reference element).

The light emitting elements of Example 6 and Comparative Example 6 were driven under the same driving conditions and optical outputs (total luminous flux) were measured. The results indicated that the optical output of light emitting element of Example 6 was improved by about 5% than the light emitting element of Comparative Example 6. Thus, it was confirmed that the present structure having the light scattering structure in the substrate was effective even when a non-polar substrate was used.

In the semiconductor light emitting element using a GaN substrate as the transparent substrate, the substrate has refractive index of 2.5, which is larger than 1.78 of the sapphire substrate. Therefore, the light extracting efficiency from the substrate side surface decreases as compared with a semiconductor light emitting element using a sapphire substrate. In Example 6 having the light scattering portions formed in the transparent substrate, higher optical output is considered to be the result of more effective improvement in light extracting efficiency than in the element using the sapphire substrate.

The semiconductor light emitting element in accordance with the present embodiment is the same as the light emitting element 100 in accordance with the first embodiment described above. It is noted, however, that in the semiconductor light emitting element in accordance with the present embodiment, the arrangement of light scattering portions formed in the transparent substrate is different from that of the first embodiment.

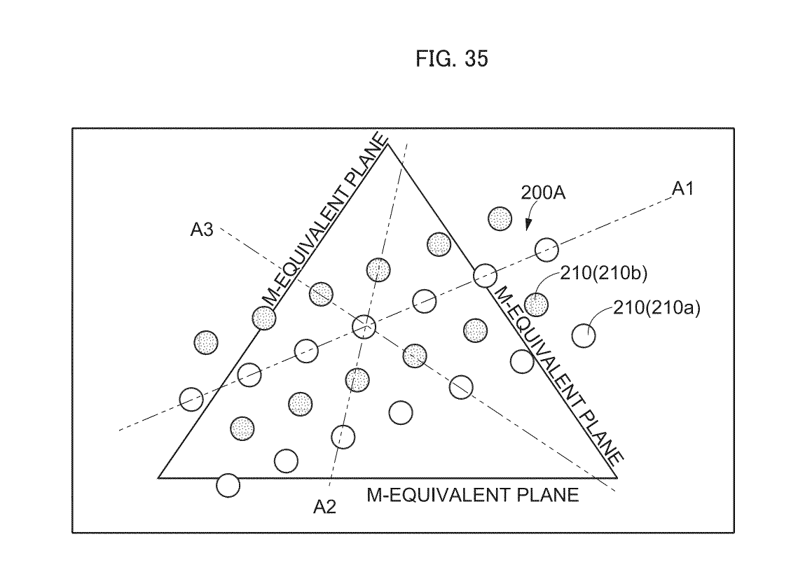

Referring to FIG. 35, light scattering structure 200A in the transparent substrate is realized by a plurality of light scattering portions 210. In the present embodiment also, as in the first embodiment, the plurality of light scattering portions form two stages of scatterer layers. In FIG. 35, the light scattering portions 210b forming the second stage of scatterer layer is hatched. In each stage, the light scattering portions 210 are formed linearly, and such lines of light scattering portions 210 are formed repeatedly in the direction intersecting the direction of extension of the lines. Thus, the plurality of light scattering portions are arranged in a plane.

Here, lines connecting adjacent light scattering portions 210 will be referred to as lines A1, A2 and A3, respectively. In the present embodiment, the plurality of light scattering portions 210 are arranged such that lines A1, A2 and A3 are not parallel to the M plane as the cleavage plane of the sapphire substrate or to the remaining two planes that are equivalent to the M plane in crystal structure (hereinafter referred to as M-equivalent planes). Specifically, the light scattering portions 210 are formed such that lines A1, A2 and A3 intersect the M plane and the M-equivalent planes.

If line A1, A2 or A3 should be parallel to the M plane or the M-equivalent plane as the cleavage plane of sapphire substrate, the sapphire substrate (transparent substrate) may possibly be broken along the line. By arranging the light scattering portions 210 forming light scattering structure 200A not to be parallel to the cleavage plane, the production yield at the time of division to the chips can be improved.

If the transparent substrate is a sapphire substrate, the cleavage plane is the M plane or M-equivalent plane. The cleavage plane differs when the substrate material is different. Therefore, when a transparent substrate other than sapphire substrate is used, the light scattering portions should preferably be arranged not to be parallel to the cleavage plane determined by the material of the substrate.

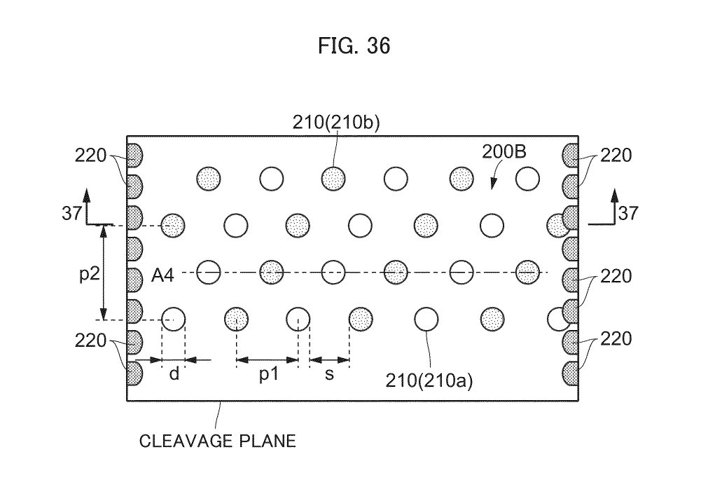

Referring to FIG. 36, the semiconductor light emitting element in accordance with the present embodiment corresponds to the semiconductor light emitting element in accordance with the thirteenth embodiment, with at least one of the lines connecting adjacent light scattering portions 210 (for example, line A4) being parallel to the cleavage plane of transparent substrate 110.

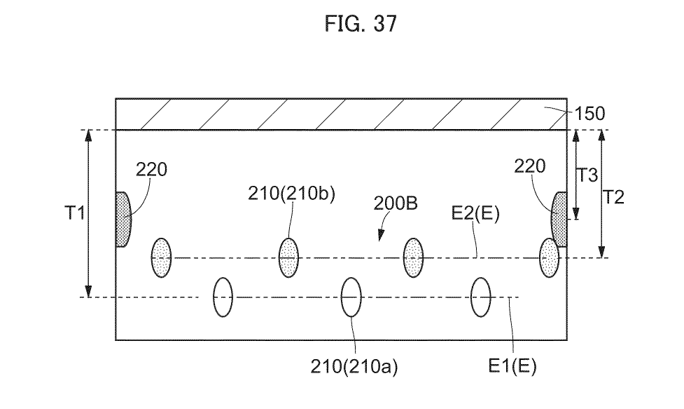

Referring to FIGS. 36 and 37, among the plurality of light scattering portions 210 arranged along line A4, adjacent light scattering portions 210 are formed at different heights (different positions in the thickness direction of transparent substrate 110).

By changing the height of adjacent light scattering portions 210, it is possible to prevent, even when the line connecting adjacent light scattering portions 210 (for example, line A4) is parallel to the cleavage plane, the substrate from being broken along the line. Thus, breaking of the substrate at an unintended position can be prevented, and the production yield at the time of division to the chips can be improved.

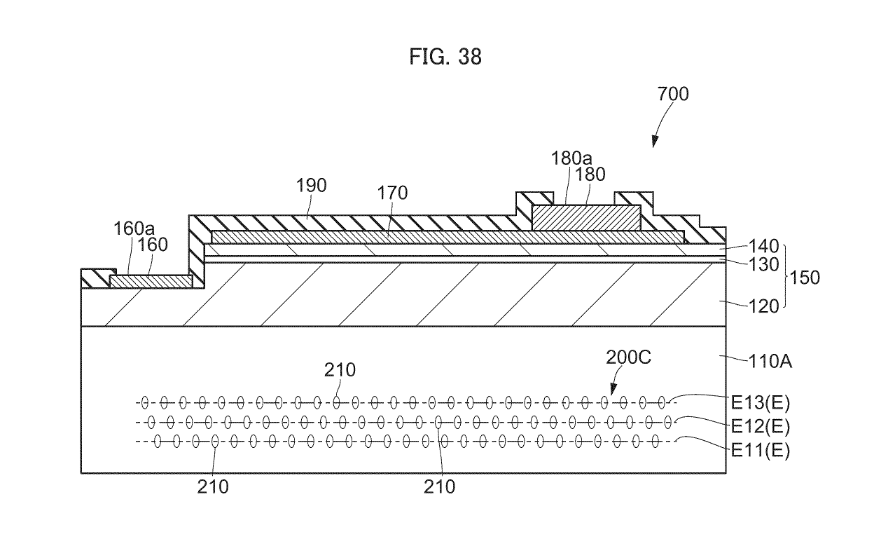

Referring to FIG. 38, a semiconductor light emitting element 700 in accordance with the present embodiment is substantially the same light emitting element as semiconductor light emitting element 100 in accordance with the first embodiment described above. It is noted, however, that the present embodiment is different in that three stages of scatterer layers E are provided, from the first embodiment having two stages of scatterer layers E.

In the present embodiment, light scattering structure 200C including scatterer layers E11, E12 and E13 is formed in transparent substrate 110A. In scatterer layers E11, E12 and E13, light scattering portions 210 forming the scatterer layers of each stage are arranged not to overlap with the light scattering portions of the scatterer layers of other stages.

As in the first embodiment described above, also in semiconductor light emitting element 700 configured in this manner, the efficiency of extracting light to the outside can effectively be improved.

In the embodiments above, examples using a sapphire substrate, a c-plane GaN substrate and an m-plane GaN substrate as the transparent substrate were described. The present invention, however, is not limited to these embodiments. The transparent substrate may be any substrate that passes light emitted from the light emitting element including the transparent substrate. Other than those described above, a nitride semiconductor substrate, an SiC substrate and a quartz substrate may be used. As the nitride semiconductor substrate, a substrate formed of AlₓGa_{y}In_{z}N (0≦x≦1, 0≦y≦1, 0≦z≦1, x+y+z=1) may be used. The nitride semiconductor substrate may be doped with Si, O, Cl, S, C, Ge, Zn, Cd, Mg or Be. For an n-type nitride semiconductor substrate, of these doping materials, Si, O and Cl are particularly preferable. Further, as the nitride semiconductor substrate, a non-polar substrate may be used.

The non-polar substrate includes apolar substrate and semipolar substrate. The main surface orientation of apolar substrate may be A plane {11-20}, M plane {1-100} and {1-101} plane. The main plane orientation of semipolar substrate includes {20-21} plane, which is known to have high light emission efficiency in, for example, green range. The present invention is also applicable to nitride semiconductor substrates having such main surface orientations.

In the embodiments above, an example using a transparent substrate having the thickness of about 120 μm has been described. The present invention, however, is not limited to such embodiments. The thickness of transparent substrate is not specifically limited, and a transparent substrate having the thickness of at least 20 μm to at most 500 μm (preferably, at least 80 μm and at most 300 μm) may appropriately be used.

In the embodiments above, the n-type impurity to be doped in each of the n-type layers is not specifically limited. It may be Si, P, As, Sb or the like, and preferably, it is Si. Further, the super lattice layer may have a super lattice structure formed by stacking at least one semiconductor layer different from the wide band gap layer or narrow band gap layer, a wide band gap layer, and a narrow band gap layer.

In the embodiment above, an example using a transparent electrode of ITO has been described. The present invention, however, is not limited to such an embodiment. As the transparent electrode, a transparent conductive film such as IZO (Indium Zinc Oxide) or the like may be used, other than ITO. Further, the n-side electrode may be W/Al, Ti/Al, Ti/Al/Ni/Au, W/Al/W/Pt/Au, Al/Pt/Au or the like, other than those described above.

Though an example using a transparent protective film formed of SiO₂ has been described in the embodiment above, the present invention is not limited to such an embodiment. As the transparent protective film, ZrO₂, TiO₂, Al₂O₃ or an oxide containing at least one element selected from the group consisting of V, Zr, Nb, Hf and Ta, SiN, BN, SiC, AlN, AlGaN or the like may be used, other than SiO₂. Preferably, the transparent protective film is an insulating film.

In the embodiment above, an example in which the n-side electrode and the p-side electrode are formed to include a protruding portion (branch electrode) has been described. The present invention, however, is not limited to such an embodiment. The n-side and p-side electrodes may have a structure not including the protruding portion (branch electrode). Further, an insulating layer for preventing current injection at a lower portion of p-side electrode may be provided at a region immediately below the p-side electrode.

In the embodiments above, an example not having the light scattering portions in the region immediately below the p-side electrode has been described. The present invention, however, is not limited to such embodiments. A configuration having the light scattering portions formed in the region immediately below the p-side electrode is also possible.

Though examples having one, two and three stages of scatterer layers formed as the light scattering structures have been described in the embodiments above, the present invention is not limited to such embodiments. Four or more multiple stages of scatterer layers may be formed.

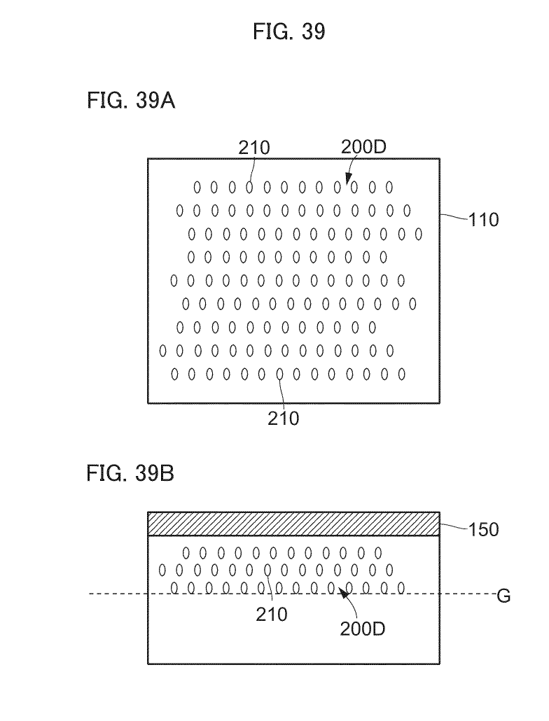

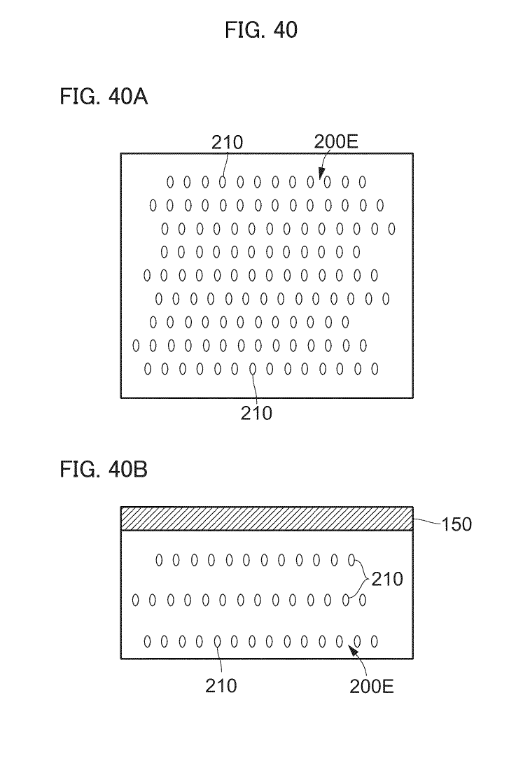

In the embodiment described above, an example has been described in which the light scattering structure is formed in the lower region of the substrate equally divided into two in the thickness direction (in the region opposite to the multi-layered structure). The present invention, however, is not limited to such an embodiment. By way of example, a light scattering structure 200D may be formed in the upper region of the substrate equally divided into two in the thickness direction (in the region on the side of multi-layered structure), as shown in FIG. 39. Further, light scattering structure 200E may be formed dispersed in the substrate (not biased), as shown in FIG. 40. Further, a light scattering structure 200F including light scattering portions 210 arranged substantially in a mountain shape when viewed in cross-section may be formed in the substrate. Further, a light scattering structure 200G having light scattering portions 210 formed in an eddy when viewed two-dimensionally may be formed in the substrate, as shown in

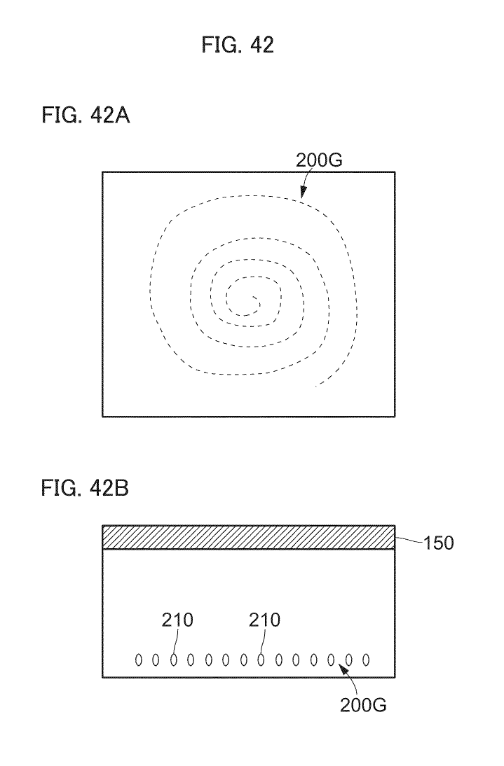

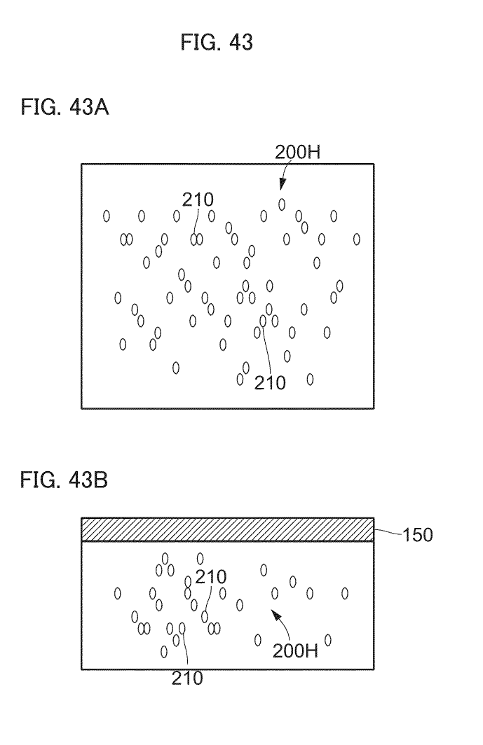

FIG. 42. Here, the light scattering portions may be arranged in a spiral. Further, a light scattering structure 200H having light scattering portions dispersed at random in the substrate may be formed in the substrate, as shown in FIG. 43.

In the embodiments above, examples in which the light scattering portion is formed to have an approximately ellipsoidal shape have been described. The present invention, however, is not limited to such embodiments. The light scattering portion may have a shape other than the approximately ellipsoidal shape. The shape, size and arrangement of light scattering portions may be appropriately adjusted so that the light entering the transparent substrate is scattered and extraction of the light from the side surface of the transparent substrate is made easier.

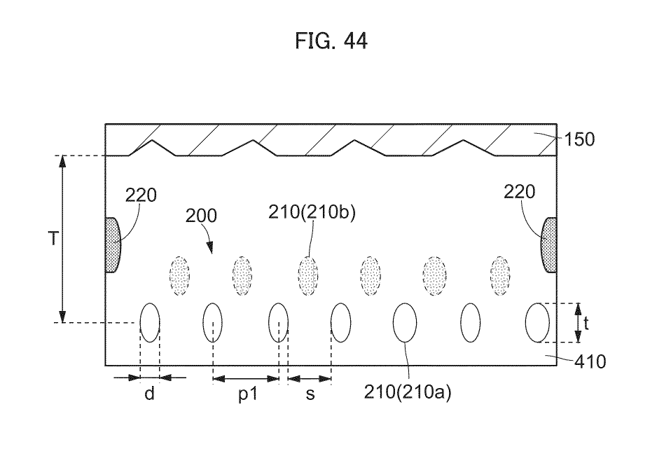

In the embodiments above, if a sapphire substrate is used as the transparent substrate, the upper surface of substrate may be flat, or it may be a PSS (Patterned Sapphire Substrate) having irregularities formed on the upper surface, such as described in Japanese Patent Laying-Open No. 2008-177528. Referring to FIG. 44, if a sapphire substrate 410 having irregularities formed on the upper surface is used, the irregularities may be protrusions and recesses having the height of about 1 to 3 μm arranged spaced apart by 1 to 3 μm from each other. Here, the distance T to the position where light scattering portions 210 are formed is defined to be the distance from the upper surface of sapphire substrate 410 to the center of light scattering portion 210 in the thickness direction, with the upper surface of sapphire substrate 410 being the bottom surface of the recesses of irregularities.

In the embodiment above, an example in which the break lines (processed portions) are formed in one stage in the transparent substrate has been described. The present invention, however, is not limited to such an embodiment. The break lines (processed portions) may also be formed in multiple stages. When the substrate thickness increases, division of the substrate becomes more difficult. Therefore, the number of stages may be increased in accordance with the thickness of the transparent substrate: for example, when the thickness of transparent substrate is in the range of about 50 to about 120 μm, the break lines (processed portions) may be formed in one stage, when the thickness of transparent substrate is in the range of about 120 to about 200 μm, the break lines (processed portions) may be formed in two stages, and when the thickness of transparent substrate is 200 μm or thicker, the break lines (processed portions) may be formed in three stages.

In the embodiment described above, an example has been described in which the scatterer layers are formed in multi-stages and the light scattering portions forming each scatterer layer are formed not to overlap with the light scattering portions of other scatterer layers when viewed two-dimensionally. The present invention, however, is not limited to such an embodiment. Part of or all of the light scattering portions forming each scatterer layer may be formed overlapped with the light scattering portions of other scatterer layers, when viewed two-dimensionally. It is noted, however, that if the light scattering portions are formed overlapped with each other, the strength at that portion decreases. Therefore, it is preferred that the light scattering portions forming each scatterer layer are formed not to overlap with the light scattering portions of other scatterer layers when viewed two-dimensionally, as described in the embodiment above.

In the first embodiment described above, as the method of manufacturing a semiconductor light emitting element, an example has been described in which the transparent substrate is ground and polished and, thereafter the light scattering portions are formed inside the transparent substrate by laser beam irradiation from the back surface side of the transparent substrate. The present invention, however, is not limited to such an embodiment. By way of example, if the surface from which the laser beam will enter has a surface roughness sufficient to form the light scattering structure at a prescribed position, the light scattering portions may be formed inside the transparent substrate by laser beam irradiation from the back surface side of transparent substrate, before grinding/polishing the transparent substrate, and thereafter, the transparent substrate may be ground and polished.

In the second to fourth embodiments above, examples have been described in which a transparent resin layer is provided outside a fluorescent layer, to cover the fluorescent layer. The present invention, however, is not limited to such embodiments. A structure not having the transparent resin layer outside the fluorescent layer is also possible. In that case, the fluorescent layer may have a shape other than the dome shape. It is also possible to seal the semiconductor light emitting element with a transparent resin not containing any fluorescent particles.

In the second embodiment, as the base for mounting the semiconductor light emitting element, various types of bases formed of ceramic material, metal material, resin material and the like may be used. If a base formed of metal material is to be used, though it is unnecessary to use a material having high reflectance with respect to the wavelength of light from the semiconductor light emitting element, use of such a material is possible. Further, the main surface of the base may be mirror-finished.

In the third and fourth embodiments above, examples have been described in which a base has a high heat radiator at a portion (where the semiconductor light emitting element is mounted). The present invention, however, is not limited to such embodiments. By way of example, the semiconductor light emitting device may be formed using a base entirely formed of a high heat radiator.

In the second to fourth embodiments above, the number of semiconductor light emitting elements mounted on the semiconductor light emitting device may be one or more.

In the fifth and sixth embodiments above, examples have been described in which the laser irradiation is done from the side of main surface (on which the multi-layered structure is formed) of the transparent substrate. The present invention, however, is not limited to such embodiments. By way of example, if the surface from which the laser beam enters has sufficient surface roughness that allows formation of the light scattering structure at a prescribed position, the laser irradiation may be done from the back surface side (opposite to the surface on which the multi-layered structure is formed) of the transparent substrate.

Embodiments realized by appropriately combining the techniques described above are also encompassed by the technical scope of the present invention.

The embodiments as have been described here are mere examples and should not be interpreted as restrictive. The scope of the present invention is determined by each of the claims with appropriate consideration of the written description of the embodiments and embraces modifications within the meaning of, and equivalent to, the languages in the claims.

By the present invention, a semiconductor light emitting element attaining high efficiency of extracting light to the outside even in the mounted state, a method of manufacturing the semiconductor light emitting element, a semiconductor light emitting device mounting such a semiconductor light emitting element, and a substrate that enhances the efficiency of extracting light to the outside of the semiconductor light emitting element can be provided.

### REFERENCE SIGNS LIST

100, 400, 500, 600, 700 semiconductor light emitting element
110 transparent substrate
110a main surface
110b side surface
120 n-type layer
130 MQW light emitting layer
140 p-type layer
150 multi-layered structure
160 n-side electrode
160a, 180a pad portion
160b, 180b protruding portion
170 transparent electrode
180 p-side electrode
190 transparent protective film
200, 200A˜200H light scattering structure
210, 210a, 210b light scattering portion
220 processed portion
1000, 2000, 3000 semiconductor light emitting device

1. A semiconductor light emitting element emitting light, comprising:
a transparent substrate having transmittance to light emitted from said semiconductor light emitting element; and
a multi-layered structure including a semiconductor multi-layered film, formed on said transparent substrate; wherein
said transparent substrate includes light scattering means formed in the transparent substrate for scattering the light that has entered the substrate.

2. The semiconductor light emitting element according to claim 1, wherein said light scattering means reflects light such that incident angle of the light to a side surface of said transparent substrate becomes smaller.

3. The semiconductor light emitting element according to claim 1, wherein said light scattering means includes a plurality of light scattering portions formed in said transparent substrate.

4. The semiconductor light emitting element according to claim 3, wherein
said plurality of light scattering portions are dispersed in a plane in said transparent substrate; and
said plurality of light scattering portions dispersed in a plane forms a scatterer layer.

5. The semiconductor light emitting element according to claim 4, wherein
in said transparent substrate, a plurality of said scatterer layers are formed; and
said plurality of scatterer layers are arranged in multiple stages to oppose to each other.

6. The semiconductor light emitting element according to claim 4, wherein
in said transparent substrate, said scatterer layers are formed in multiple stages; and
said light scattering portions forming each of the scatterer layers are arranged not to overlap with said light scattering portions of the scatterer layers of other stages.

7. The semiconductor light emitting element according to claim 3, wherein each of said plurality of light scattering portions has an approximately ellipsoidal shape extending in thickness direction of said transparent substrate.

8. The semiconductor light emitting element according to claim 3, further comprising
a transparent electrode layer formed on said multi-layered structure; and
said plurality of light scattering portions are formed in a region immediately below said transparent electrode layer.

9. The semiconductor light emitting element according to claim 8, further comprising
a metal electrode layer formed to overlap with said transparent electrode layer; and
said plurality of light scattering portions are formed in a region immediately below said transparent electrode except for a region immediately below said metal electrode layer.

10. The semiconductor light emitting element according to claim 3, wherein
said transparent substrate is thicker than 10 μm; and
each of said plurality of light scattering portions is formed at a position apart by a distance of at least 10 μm in thickness direction from a surface on which said multi-layered structure is formed, of said transparent substrate.

11. The semiconductor light emitting element according to claim 3, wherein at least some of said plurality of light scattering portions are arranged in a line.

12. The semiconductor light emitting element according to claim 11, wherein direction of extension of said light scattering portions arranged in a line intersects a cleavage plane of said transparent substrate.

13. The semiconductor light emitting element according to claim 3, wherein said light scattering portion is formed of a heat denatured region.

14. The semiconductor light emitting element according to claim 5, wherein
on a side surface portion of said transparent substrate, a processed portion processed by laser irradiation and used as a start point for dividing said transparent substrate is formed; and
in said transparent substrate, position of said scatterer layer in said thickness direction is different from position of said processed portion in the thickness direction.

15. The semiconductor light emitting element according to claim 1, wherein said transparent substrate is any of a sapphire substrate, a nitride semiconductor substrate, a SiC substrate and a quartz substrate.

16. A method of manufacturing a semiconductor light emitting element, comprising the steps of:
forming a multi-layered structure including a semiconductor multi-layered film on one surface of a substrate;
removing the other surface of said substrate not having said multi-layered structure formed thereon until said substrate reaches a prescribed thickness;
directing a laser beam from the side of said the other surface to the inside of said substrate and thereby forming, in said substrate, a light scattering portion scattering light that has entered said substrate; and
dividing said substrate to individual semiconductor light emitting elements.

17. The method of manufacturing a semiconductor light emitting element according to claim 16, wherein said step of forming said light scattering portion includes the step of forming said light scattering portion close to said the other surface of said substrate.

18. The method of manufacturing a semiconductor light emitting element according to claim 17, wherein said step of forming said light scattering portion close to said the other surface includes the step of forming said light scattering portion closer to said the other surface than an intermediate position between said one surface and said the other surface in the thickness direction of said substrate.

19. A method of manufacturing a semiconductor light emitting element, comprising the steps of:
directing a laser beam from the side of one surface of a substrate and thereby forming, in said substrate, a light scattering portion scattering light that has entered said substrate;
forming a multi-layered structure including a semiconductor multi-layered film on said substrate;
removing a surface of said substrate not having said multi-layered structure formed thereon until said substrate reaches a prescribed thickness; and
dividing said substrate to individual semiconductor light emitting elements.

20. The method of manufacturing a semiconductor light emitting element according to claim 19, wherein said step of forming said light scattering portion includes the step of forming said light scattering portion close to a surface of said substrate having said multi-layered structure formed thereon.

21. The method of manufacturing a semiconductor light emitting element according to claim 19, wherein
with the surface of said substrate having said multi-layered structure formed thereon being one surface and the surface of said substrate opposite to said surface having said multi-layered structure formed thereon being the other surface,
said step of forming said light scattering portion includes the step of forming said light scattering portion on the side closer to said the other surface than an intermediate position between said one surface and said the other surface in the thickness direction of said substrate.

22. The method of manufacturing a semiconductor light emitting element according to claim 21, wherein said step of removing includes the step of removing said the other surface of said substrate so that said light scattering portion is provided close to said the other surface of said substrate.

23. The method of manufacturing a semiconductor light emitting element according to claim 19, wherein said step of forming said light scattering portion includes the step of directing a laser beam from the side of the surface of said substrate having said multi-layered structure formed thereon.

24. A semiconductor light emitting device, comprising:
a semiconductor light emitting element; and
a mounting portion for mounting said semiconductor light emitting element; wherein
said semiconductor light emitting element includes a substrate and a multi-layered structure including a semiconductor multi-layered film formed on said substrate; and
a light scattering portion scattering light that entered said substrate is formed inside said substrate.

25. The semiconductor light emitting device according to claim 24, wherein said mounting portion is formed of a heat radiator radiating heat from said semiconductor light emitting element.

26. The semiconductor light emitting device according claim 25, wherein said heat radiator is formed of a material containing at least one selected from the group consisting of Al, Ag, Au, Cu, Mo, W, Sn, C, SiC, AlN and Si.

27. The semiconductor light emitting device according to claim 24, further comprising a coupling layer formed of a metal material having low melting point, for coupling said semiconductor light emitting element to said mounting portion.

28. The semiconductor light emitting device according to claim 24, further comprising:
a wavelength converting portion for converting wavelength of light from said semiconductor light emitting element; and
a reflection portion provided outside said wavelength converting portion, for reflecting light emitted from said semiconductor light emitting element.

29. The semiconductor light emitting device according to claim 24, wherein said wavelength converting portion contains at least one type of fluorescent substance.

30. A light transmitting substrate, comprising
a plurality of light scattering portions formed inside said substrate for scattering light that entered said substrate; wherein
said plurality of light scattering portions are dispersed in a plane in said substrate.
